(19) United States
(12) Patent Application Publication
(10) Pub. No.: US 2026/0177909 A1
(43) Pub. Date: Jun. 25, 2026

(54) IMAGING MEDIA WITH DUAL LAYER DEVELOPER STRUCTURE

(71) Applicant: Polaroid IP B.V., Enschede (NL)

(72) Inventors: Wei YOU, Taichung City (TW); Ting-Hsuan LIN, Pingtung County (TW); Yuliana TASSIA, Jakarta (ID); Rong Chang LIANG, Cupertino, CA (US)

(21) Appl. No.: 19/000,295

(22) Filed: Dec. 23, 2024

(51) Int. Cl. G03F 7/00; G03F 7/09

(52) U.S. Cl. CPC G03F 7/002; G03F 7/094

(57) ABSTRACT

Imaging systems, apparatus, developer systems and methods are provided which includes a two-layer developer comprising a low-haze clear developer layer (Dc) and a microporous translucent developer layer (Dp). The microporous translucent developer layer is deposited between an imaging layer which includes photosensitive microcapsule layer and the low-haze clear developer layer. The resulting imaging sheets achieve improved image color saturation, an improved rate of image development and enhanced dye mixing, and an improved printing energy efficiency as well as an improved weatherability or discoloration resistance of the developed image.

### FIELD

The present technology generally relates to systems, media, and methods used for processing articles, and more particularly to a dual layer developer structure containing systems, media, apparatus, and methods for improving imaging media.

### BACKGROUND

The following discussion is provided to aid the reader in understanding the disclosure and is not admitted to describe or include prior art thereto.

Single-sheet, self-containing, full-color microcapsule imaging systems (e.g., Cycolor) comprising microcapsules encapsulated therein a photo-hardenable or photo-softenable composition and a leuco-dye as the internal phase have been known for years. For example, the photohardenable microcapsules are image-wise hardened by actinic radiation, and upon passing the exposed imaging sheet through a pressure roller, the microcapsules may be image-wise ruptured to release the internal phase. The leuco dyes thus released migrate to a developer material and react to form a full-color image with its color density (or grayscale) modulated by the exposure energy (time or pulse width), intensity (pulse amplitude), and/or pulse frequency.

To develop high quality, continuous-tone full-color images with a high color saturation, a high temperature post-heating/calendering step is often needed after the capsules are ruptured to (1) facilitate the leuco-dyes/developer reaction, (2) increase the degree of mixing of for example, the cyan, magenta and yellow leuco-dyes released from the unexposed and partially exposed red-, green- and blue-sensitive microcapsules, respectively, and (3) reduce the haze and improve the color reflectivity of the image layer. However, the requirements of low power consumption, light weight, and small footprint in many, if not all, of the battery-operated portable applications severely limit the use of high temperature and pressure in the printing process. An energy-saving and low-pressure solution is needed to address these issues.

The use of a non-photopolymerizable reactive epoxidized diluent/plasticizer either in the photosensitive leuco-dye microcapsules or in a separate non-photosensitive microcapsule is described in US Publication No. 2023/0393459A1 to facilitate the development of the leuco-dyes and the mixing of the dyes. Improvements in the color saturation as well as the low temperature exposure latitude of the microcapsule imaging system were reported. The degree of discoloration or yellowness in the Dₘᵢₙ (minimum color density) areas was also reduced, which may be due to the reaction of the epoxy group of the diluent with the phenol group of the dye developer. Another patent application, US Publication No. 2023/0393460 to the same Applicant discloses a primer layer comprising a polymeric hollow particle and a white particulate having improved image color saturation and reduced printing power consumption. The entire contents of these applications are incorporated herein by reference in their entireties, including for the primers, microcapsules, and microcapsule imaging sheets disclosed therein.

Although the image quality was improved by the measures disclosed in the two above-mentioned patent applications, the image color saturation, rate of image development and the degree of dye mixing, particularly in the low color density areas still require further improvements to meet the needs for high-quality, portable applications. The present technology is directed to overcoming these and other deficiencies.

### SUMMARY

In one aspect, which may be combined with any other aspect or embodiment, the present disclosure relates to an imaging system comprising: a) a microporous developer layer (Dp) comprising one or more dye developers, one or more UV absorbers and optionally one or more optical brighteners; b) a low-haze, clear developer layer (Dc) overlying the microporous developer layer and comprising one or more dye developers, one or more optical brighteners and optionally one or more UV absorbers; wherein the concentration of dye developers in the low-haze, clear developer layer (Dc) is preferably lower than the concentration of the dye developers in the microporous layer (Dp).

In some embodiments, the one or more dye developer in the microporous layer is the same as the one or more dye developer in the low-haze, clear developer layer. In some embodiments, the dye developer is amorphous or crystalline. In some embodiments, the one or more dye developer is a leuco-dye developer. In some embodiments, the dye developer is selected from the group consisting of Lewis acids, acid clay, phenolic resins, novolac resins, salicylic acid, oxalic acid, phthalic acid, and their derivatives, metal complexes, and copolymers, blends, or composites thereof. In some embodiments, the dye developer comprises a metal salt of salicylic acid, phenolic resins, and their blends or copolymers. In some embodiments, the developer is zinc 3,5-bis(alpha-methylbenzyl) salicylate, zinc 3,5-dialkylsalicylate, or zinc salts of salicylate-encapped or grafted novolac resins.

In some embodiments, the low-haze clear developer layer comprises from about 5 wt. % to about 90 wt. %, based on the dry weight of the low-haze clear developer layer, of one or more dye developers. In some embodiments, the low-haze clear developer layer comprises from about 10 wt. % to about 50 wt. %, based on the dry weight of the low-haze clear developer layer, of one or more dye developers. In some embodiments, the microporous developer layer comprises from about 70 wt. % to about 98 wt. %, based on the dry weight of the microporous developer layer, of one or more dye developers. In some embodiments, the microporous developer layer comprises from about 80 wt. % to about 95 wt. %, based on the dry weight of the microporous developer layer, of one or more dye developers.

In some embodiments, each of the microporous developer layer and the low-haze clear developer layer further comprises one or more binders. In some embodiments, the binder in the low-haze clear developer layer has a lower minimum film formation temperature (MFFT) or glass transition temperature (T_{g}), or both than that of the binder in the microporous developer layer.

In some embodiments, the imaging layer has a thickness of from about 6 μm to about 18 μm. In some embodiments, the microporous developer layer has a thickness of from about 5 μm to about 14 μm. In some embodiments, the microporous developer layer has a thickness of from about 7 μm to about 11 μm. In some embodiments, the low-haze clear developer layer has a thickness of from about 2 μm to about 10 μm. In some embodiments, the low-haze clear developer layer has a thickness of from about 3 μm to about 6 μm.

In some embodiments, the concentration of optical brightener in the low-haze, clear developer layer is higher than the concentration of the optical brightener in the microporous layer. In some embodiments, the microporous layer does not include an optical brightener. In some embodiments, the concentration of UV absorber in the low-haze, clear developer layer is lower than the concentration of the UV absorber in the microporous layer. In some embodiments, the low-haze, clear developer layer does not include a UV absorber.

In some embodiments, the imaging system further includes an imaging layer in contact with the microporous developer layer and comprising one or more photosensitive microcapsules; said one or more photosensitive microcapsules comprising a leuco-dye and a multifunctional photo-polymerizable or photocrosslinkable monomer or oligomer. In some embodiments, the one or more photosensitive microcapsules is photo-hardenable, photo-crosslinkable, or photo-polymerizable. In some embodiments, the one or more photosensitive microcapsules comprises a mixture of two or more leuco-dyes, selected from the group consisting of a black leuco-dye, a cyan leuco-dye, a magenta leuco-dye, a yellow leuco-dye, a red leuco-dye, a green leuco-dye, and a blue-leuco dye.

In some embodiments, the imaging system further includes an under-layer comprising one or more microcapsules, wherein the one or more microcapsules include (i) a solvent, plasticizer or a diluent for the leuco-dye in the photosensitive microcapsule or the leuco-dye developer; and/or (ii) a multifunctional photo-polymerizable or cross-linkable monomer or oligomer, and a black leuco-dye or leuco-dye system. In some embodiments, the under-layer is a primer layer, an adhesive layer or tie layer. In some embodiments, the imaging layer or the under-layer is overlaid on to one surface of a first substrate. In some embodiments, the imaging system further includes a second substrate with the low-haze clear developer layer deposited thereon.

In one aspect, which may be combined with any other aspect or embodiment, the present disclosure relates to an imaging system, comprising: a) a first substrate having two sides; b) optionally an under-layer overlaying one side of the first substrate comprising one or more microcapsules; c) an imaging layer overlying the under-layer and comprising one or more photosensitive microcapsules; said photosensitive microcapsule comprising a leuco-dye, a multifunctional photo-polymerizable or photocrosslinkable monomer or oligomer; d) a microporous developer layer (Dp) comprising one or more dye developers, one or more UV absorbers and optionally one or more optical brighteners; e) a low-haze, clear developer layer (Dc) overlying the microporous developer layer and comprising one or more dye developers, one or more optical brighteners and optionally one or more UV absorbers; and f) a second substrate overlaying the low-haze, clear developer layer.

These and other features, together with the organization and manner of operation thereof, will become apparent from the following detailed description when taken in conjunction with the accompanying drawings.

### BRIEF DESCRIPTION OF THE DRAWINGS

The details of one or more embodiments are set forth in the accompanying drawings and the description below. Other features, aspects, and advantages of the disclosure will become apparent from the description, the drawings, and the claims. In the drawings, like reference numerals are used throughout the various views to designate like components.

FIG. 1 is a schematic illustration of an embodiment of an imaging sheet having a 2-layer developer comprising a low-haze clear developer layer (Dc) and a microporous translucent developer layer (Dp), according to one embodiment of the present disclosure.

FIGS. 2A and 2B show the SEM micrographs of a low-haze Dc layer (2A) having a high degree of film formation, and a highly microporous Dp layer (2B) having a low degree of film formation. The Dc and Dp layers are of essentially the same composition, but exhibit dramatically different morphology.

It will be recognized that some or all of the figures are schematic representations for purposes of illustration. The figures are provided for the purpose of illustrating one or more embodiments with the explicit understanding that they will not be used to limit the scope or the meaning of the claims. The depiction of a particular height, length, width, relative sizing, number of chambers, sub-chambers, and the like, are intended to serve as examples only, and are not intended to limit the scope of the present technology.

### DETAILED DESCRIPTION

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s).

Features may be described herein as part of the same or separate aspects or embodiments of the present technology for the purpose of clarity and a concise description. It will be appreciated by the skilled person that the scope of the present technology may include embodiments having combinations of all or some of the features described herein as part of the same or separate embodiments.

Various techniques and mechanisms of the present technology will sometimes be described in singular form for clarity. However, it should be noted that some embodiments include multiple iterations of a technique or multiple instantiations of a mechanism unless noted otherwise. In the following description, numerous specific details are set forth in order to provide a thorough understanding of the present technology. Particular example embodiments of the present technology may be implemented without some or all of these specific details. In other instances, well known process operations have not been described in detail.

The following terms are used throughout and are as defined below.

As used herein and in the appended claims, singular articles such as “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of refereeing individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified. The expression “comprising” means “including, but not limited to.” Thus, other non-mentioned substances, additives, carriers, or steps may be present. Unless otherwise specified, “a” or “an” means one or more.

Unless otherwise indicated, all numbers expressing quantities of properties, parameters, conditions, and so forth, used in the specification and claims are to be understood as being modified in all instances by the term “about.” Accordingly, unless indicated to the contrary, the numerical parameters set forth in the following specification and attached claims are approximations. Any numerical parameter should at least be construed in light of the number reported significant digits and by applying ordinary rounding techniques. The term “about” when used before a numerical designation, e.g., temperature, time, amount, and concentration including range, indicates approximations which may vary by (+) or (−) 10%, 5% or 1%.

As will be understood by one of skill in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member.

A color developer is a key component of photosensitive microcapsule imaging systems and is typically an acidic compound with proton-donating-ability.

Upon the rupture of the photo-hardenable microcapsules during the pressure development step, the leuco-dye as well as the multifunctional monomer/oligomer encapsulated therein are released from the unhardened or partially hardened microcapsules. The leuco-dye may migrate to the developer layer by a dissolution, diffusion, and/or capillary flow process. The capillary flow process is typically a significantly faster process than the dissolution and diffusion processes, particularly in a polymeric developer layer, but requires a developer layer of favorable surface energy and microporous morphology to ensure a fast flow rate and in turn a fast rate of color development or a high fresh Dmax. On the other hand, to maintain a high microporosity during coating, converting, storage and transportation of the image media, a developer layer with a high glass transition temperature (T_{g}) is often required. However, to achieve a high-quality image of high color saturation with low graininess and mottle, a high-temperature post heating or calendering step after the pressure development is required for imaging media with such a high T_{g}, highly microporous developer layer to ensure a high degree of film formation of the dye-developer layer to minimize the light scattering effect due to the microporosity. A high post heating/calendaring temperature is also required to ensure a high conversion of the dye development reactions as well as a thorough and uniform mixing of various dyes in the high T_{g} developer layer. However, in the mid-tone image areas where the microcapsules are partially hardened, a less amount of internal phase with a higher viscosity may be released from the ruptured capsules than those in the Dmax (maximum color density) areas. Insufficient film formation and/or dye mixing in the mid-tone image areas have become major technical challenges to overcome for the microcapsule imaging systems, particularly in the battery-operated portable applications where a high temperature post heating/calendaring process is very difficult, if not impossible, to implement. Additionally, it has been found that an excess of developer or a thick developer layer is often needed to avoid the fading of the developed dyes via the deprotonation and/or the reversible ring closure mechanisms of the dyes. However, a thick, microporous developer layer tends to result in a poor Dₘᵢₙ stability and/or a worse weatherability and discoloration of the image media after aging due to the thermo- and/or photo-oxidation of the developers, particularly those with a phenolic derivative. A thick, high T_{g}, microporous developer layer makes the energy management even more difficult for the portable printing of high quality images. The present inventors have discovered an improved photosensitive imaging system with a two-layer developer structure which addresses these issues.

Various embodiments of the present technology described herein relate to systems, apparatus, developer systems media, and methods for photosensitive media applications. The present inventors discovered that using an image media with a microporous developer layer typically showed a significantly faster color development and a higher color saturation than those with a non-microporous developer layer, presumably by the capillary effect to quickly pull the unhardened internal phase including the leuco dyes dissolved or dispersed therein into the developer layer.

An aspect of the invention is directed to the use of a developer comprising a first layer and a second layer, namely, a low-haze clear developer layer (Dc) and a microporous translucent developer layer (Dp), wherein the microporous translucent developer layer is deposited between an imaging layer which includes photosensitive microcapsule layer and the low-haze clear developer layer.

In one aspect, the present technology provides improved imaging media which includes a two-layer developer comprising a low-haze clear developer layer (Dc) and a microporous translucent developer layer (Dp). In one aspect, a low-haze Dc layer is provided which comprises a lower concentration of dye developers than that of the microporous Dp layer. The developer used in the De layer may be the same as or different from the developer used in the Dp layer. In yet another aspect, a Dc layer is provided which comprises a binder with a minimum film formation temperature (MFFT) or glass transition temperature (T_{g}) lower than that of the binder of the Dp layer. To improve the transparency and reduce the haze of the Dc layer, a developer with a high compatibility with the binder is used in Dc layer. In yet another aspect, the compositions of the Dc and Dp layers are the same except that the difference in their degree of film formation or the microporosity is achieved by the manufacturing processes including, but are not limited to, varying the drying temperature during coating, the use of a non-solvent to increase the microporosity of the Dp layer, the use of a coalescing solvent or a post heating/calendering process to improve the degree of film formation of the Dc layer . . . etc.

In another aspect, the present technology provides an imaging system comprising a) a first substrate having two sides; b) an imaging layer overlaying on one side of the first substrate comprising one or more microcapsules (e.g., photosensitive microcapsules); c) a microporous developer layer (Dp); d) a low-haze developer layer overlaying on the microporous developer layer (Dc); and e) a second substrate overlaid on the low-haze developer layer. In some embodiments, the low-haze Dc layer comprises a lower concentration of dye developers than that of the microporous developer layer. In some embodiments, the Dc layer comprises a binder with a minimum film formation temperature (MFFT) or glass transition temperature (T_{g}) lower than that of the binder of the Dp layer.

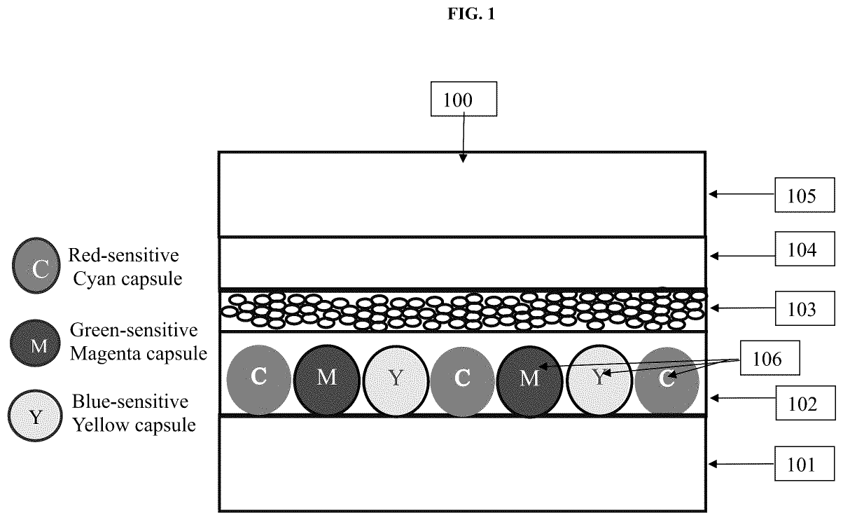

Referring to FIG. 1, in some embodiments, a microcapsule imaging system 100 according to the present disclosure includes an imaging layer 102, comprising microcapsules 106 (e.g., photosensitive microcapsules), disposed on a first substrate 101. The imaging layer is further in contact with a microporous developer layer 103, which is overlaid with a low-haze clear developer layer 104. The low-haze clear developer layer is disposed on a second substrate 105. The microcapsule imaging system may optionally include an under-layer or a primer layer (not shown) in contact with the first substrate and/or the imaging layer 102.

### The Two-Layered Developer System

The imaging system of the present technology includes a multi-layer developer structure. In some embodiments, the imaging system comprises a two-layer developer structure. In some embodiments, the developer layer(s) include one or more leuco-dye developers. In some embodiments, the two-layer developer structure comprises a microporous developer layer (Dp) and a low-haze, clear developer layer (Dc). In some embodiments, the microporous developer layer is overlaid, overcoated, or laminated onto a photosensitive microcapsule imaging layer, which in turn is overlaid on to one surface of a first substrate. In some embodiments, the microporous developer layer (Dp) is deposited between the photosensitive microcapsule imaging layer and the low-haze, clear developer layer (Dc). In some embodiments, the photosensitive microcapsule imaging layer is overlaid, over-coated or laminated onto the microporous developer layer (Dp) which is overlaid, overcoated or laminated onto the low-haze, clear developer layer (Dc) on a second substrate, and the resultant multilayer coating sheet is laminated with a first substrate which is optionally precoated with an adhesive, a tie layer, a primer layer or an underlayer. In some embodiments, the low-haze, clear developer layer (Dc) layer is deposited between the microporous developer layer (Dp) and a second substrate. The developer layer(s) may be placed in contact with the adjacent layers or the substrate by for example, lamination after being applied to the layer or substrate. In some embodiments, the developer layer may be over-coated onto the imaging layer and the resultant over-coated sheet is used as-is, without the second substrate. In some embodiments, the over-coated developer/imaging layer may be further over-coated with an optically-clear durable protective coating or laminated with a second substrate, optionally with an additional adhesive layer.

The chemical composition of the Dp layer and De layer may be the same or different. In some embodiments, the developer in the Dp layer has the same chemical composition as that in the Dc layer. In some embodiments, the developer in the Dp layer has a different chemical composition as that in the Dc layer. In some embodiments, the Dp layer and the Dc layer may each have the different developer concentration. The variation in the developer concentration and/or morphology between the two developer layers results in advantages such as reduction in discoloration after aging while maintaining the color fastness of the developed images.

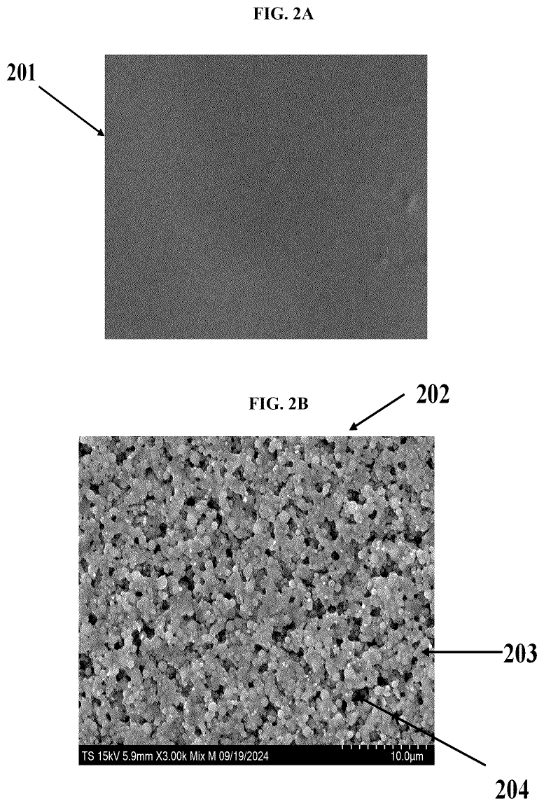

In some embodiments, the Dc layer and the Dp layer may have the same chemical composition but different morphology as shown in FIGS. 2A and 2B, respectively. The SEM micrograph of the Dc layer (201) shows a high degree of film formation without observable porosity. In contrast, the SEM micrograph of the Dp layer (202) of essentially the same chemical composition shows a very low degree of film formation with a high % of microporosity. The particulate morphology of the leuco-dye developer (203) and the micropores (204) of the Dp layer (202) can be seen very clearly.

The developer used in the Dp layer and De layer may be an amorphous or crystalline material. Suitable developers utilized in the Dp layer and Dc layer may include, but are not limited to a Lewis acid, an acid clay, or one or more compounds comprising a phenol group or carboxylic acid group, or metal complexes and/or derivatives thereof, and combinations thereof. In some embodiments, the developer layer comprises one or more leuco dye developers. By way of non-limiting example, the leuco-dye developers may comprise Lewis acids, silicic acids, salicylic acid derivatives, benzoic acid derivatives, oxalic acid derivatives, phthalic acid derivatives, phenolic resins, novolac resins, and their metal complexes, particularly zinc complexes, or blends, composites, copolymers including graft and block copolymers, or combinations thereof. In some embodiments, the leuco-dye developer is selected from the group consisting of Lewis acids, acid clay, phenolic resins, novolac resins, salicylic acid, oxalic acid, and their derivatives, zinc complexes, copolymers, blends or composites. Illustrative developer(s) may include, without limitation, acid clay, zinc 3,5-bis(alpha-methylbenzyl) salicylate (e.g., N-054-W, R-054 from SANKO Co., Ltd.), zinc 3,5-di-t-butyl salicylate, zinc 3,5-dioctyl salicylate, HRJ 4542 (Schenectady Chemical and Sumitomo Chemical), or novolac resin developers such as RD9870, RD9870A, RD9880, RD9880U, RF-118, etc. (Xinxiang Richful Lube Additive Co., Ltd.). In some embodiments, the developer includes a zincated derivative of an acid. In some embodiments, the developer is a metal salt of salicylic acid, for example zinc salicylate. In some embodiments, the developer is zinc 3,5-bis (alpha-methylbenzyl) salicylate. In another embodiment, the developer includes a metal salt of salicylic acid such as zincated salicylate derivative, phenolic or novolac types of developers, and their blends or copolymers. In some embodiments, the developer is zinc 3,5-bis(alpha-methylbenzyl) salicylate, zinc 3,5-dialkylsalicylate, or zinc salts of salicylate-encapped or grafted novolac resins.

The one or more developers may be present in the one or more developer layers or any other layer at a concentration by weight, relative to the dry weight of the developer layer or other layer, of greater than or equal to about 10 wt. %, greater than or equal to about 20 wt. %, greater than or equal to about 30 wt. %, greater than or equal to about 40 wt. %, greater than or equal to about 50 wt. %, greater than or equal to about 55 wt. %, greater than or equal to about 60 wt. %, greater than or equal to about 65 wt. %, greater than or equal to about 70 wt. %, greater than or equal to about 75 wt. %, greater than or equal to about 80 wt. %, greater than or equal to about 85 wt. %, greater than or equal to about 90 wt. %, greater than or equal to about 95 wt. %, greater than or equal to about 96 wt. %, greater than or equal to about 97 wt. %, greater than or equal to about 98 wt. %, greater than or equal to about 99 wt. %, or any range or value therein between. In some embodiments, the developer(s) may be present at a concentration by weight, relative to the dry weight of the developer layer, of at least about 1 wt. %, at least about 2 wt. %, at least about 3 wt. %, at least about 4 wt. %, at least about 5 wt. %, at least about 6 wt. %, at least about 7 wt. %, at least about 8 wt. %, at least about 9 wt. %, at least about 10 wt. %, at least about 15 wt. %, at least about 20 wt. %, at least about 25 wt. %, at least about 30 wt. %, or any range or value therein between.

In some embodiments, the Dc layer may include a different concentration of the developer from that of the Dp layer. In other embodiments, the low-haze Dc layer comprises a lower concentration of dye developers than that of the microporous Dp layer. The difference in concentration of the developer in the two layers helps to reduce discoloration after aging while maintaining the color fastness of the developed images. In some embodiments, the concentration of one or more developers in the Dc layer may range from about 3% to about 95% by weight, relative to the dry weight of the Dc developer layer, including without limitation, from about 5% to about 85%, from about 5% to about 80%, from about 5% to about 75%, from about 6% to about 70%, from about 7% to about 60%, from about 8% to about 65%, from about 10% to about 50%, from about 15% to about 40% or from about 20% to about 35%, by weight of the total weight of the Dc developer layer or any range including and/or in-between any two of these values. In some embodiments, the concentration of one or more developers in the Dp layer may range from about 50% to about 99.9% by weight, relative to the dry weight of the Dp developer layer, including without limitation, from about 55% to about 99.5 %, from about 60% to about 99%, from about 65% to about 98.5%, from about 70% to about 98%, from about 75% to about 96%, from about 80% to about 95%, from about 82% to about 92%, or from about 85% to about 90%, by weight of the total weight of the Dp developer layer or any range including and/or in-between any two of these values.

In some embodiments, the Dc layer may include about 5% to about 90% by weight of one or more developers. In some embodiments, the Dc layer may include about 10% to about 50% by weight of one or more developers. In some embodiments, the Dp layer may include about 50% to about 98% by weight of one or more developers. In some embodiments, the Dp layer may include about 60% to about 95% by weight of one or more developers.

In some embodiments, the ratio of concentration of one or more developers in the Dc layer to the concentration of one or more developers in the Dp layer may range from about 1:16 to about 1:1.05, including from about 1:14 to about 1:1.03, from about 1:10 to about 1:1.5, from about 1:8 to about 1:2, from about 1:7 to about 1:2, or from about 1:5 to about 1:3, or any range or value therein.

In some embodiments, the developer layers may comprise one or more additives such as binders, fillers, optical brighteners, and/or UV absorbers. In some embodiments, the developer layer may comprise a polymeric binder, particularly a latex binder. Suitable binders, may include, without limitation, acrylic products, including acrylic latexes (e.g., Joncryl® 95 by BASF, P-208M1, P-208M3, P-208M4 and P-208M6 from Chang Chun Group Crop.; Primal AC-261T from Dow; Hycar 2679 and 26138 from Lubrizol), carboxylated, styrene-acrylic copolymer emulsion (e.g., Hycar® 26-1199 from Lubrizol), styrene-acrylic copolymer emulsion Joncryl 352D, Joncryl 7168 and Joncryl 1686 from BASF, and the blends and combinations thereof. Other useful latex binders include, but are not limited to, ethylene-vinyl acetate latexes, styrene-butadiene latexes, polyurethane latexes, and their copolymers or blends. In some embodiments, the Dc layer includes a binder with a minimum film formation temperature (MFFT) or glass transition temperature (T_{g}) lower than that of the binder in the Dp layer. In some embodiments, a binder with a high compatibility with the developer used in Dc layer is used in order to improve the transparency and reduce the haze of the Dc layer. The amount of binder can range from about 0% to about 20%, including from about 0.1% to about 10%, about 0.5% to about 5%, about 0.8% to about 4%, about 0.9% to about 3%, or about 1% to about 2%, of the total weight of the Dc or Dp developer layer or any range including and/or in-between any two of these values.

In another embodiment, the developer layers may comprise of one or more optical brightener and/or ultraviolet (UV) absorbers to further improve the out-door discoloration resistance of the imaging media. The efficacy of the optical brighter(s) and UV absorber(s) may be significantly improved by having a higher concentration of the optical brighter in the Dc layer than that in the Dp layer and a higher concentration of the UV absorber(s) in the Dp layer than that in the Dc layer. Accordingly, in some embodiments, the Dc layer comprises an optical brighter but no UV absorber. In some embodiments, the Dp layer comprises an UV absorber but no optical brighter or relatively less optical brighter than in the Dc layer. In some embodiments, the developer layer may comprise a polymeric binder and an optical brightener. In some embodiments, the developer layer may comprise a polymeric binder and an UV absorber. In some embodiments, the developer layer may comprise a polymeric binder, an optical brightener, and an UV absorber.

Suitable optical brighteners may include, without limitation, 4,4′-bis(2-sulfostyryl)-biphenyl disodium salt (e.g., Doubletex CBS-1), 2,5-Bis (5-tert-butyl-2-benzoxazolyl)thiophene, and 4,4′-Bis (2-benzoxazolyl) stilbene (DOUBLETEX OB-1) from Taiwan Doubletex Corporation, and Disodium 4,4′-Bis (2-Sulfonatostyryl) biphenyl (e.g., Tinopal CBS-X from BASF). The amount of optical brightener can range from about 0% to about 10%, including from about 0.1% to about 8%, about 0.5% to about 5%, about 0.8% to about 4%, about 0.9% to about 3%, or about 1% to about 2%, of the total weight of the Dc or Dp developer layer or any range including and/or in-between any two of these values.

Suitable UV absorbers may include, without limitation, triazine-based UV absorbers (e.g., Tinuvin 400DW, Tinuvin® 400, Tinuvin® 405, Tinuvin® 460, Tinuvin® 477, Tinuvin® 479 from BASF), and benzotriazole UV Absorbers (e.g., Tinuvin® 384-2, Tinuvin® 1130, Tinuvin® 900, Tinuvin® 928 from BASF). The amount of UV absorbers can range from about 0% to about 5%, including from about 0.01% to about 4%, about 0.02% to about 3%, about 0.03% to about 2%, about 0.05% to about 1%, about 0.08% to about 0.75%, or about 0.1% to about 0.5%, of the total weight of the De or Dp developer layer or any range including and/or in-between any two of these values.

The developer layer(s) may have a thickness of at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 15 μm, at least about 20 μm, at least about 25 μm, at least about 30 μm, at least about 35 μm, at least about 40 μm, at least about 45 μm, at least about 50 μm, or any range or value therein. In some embodiments, the developer layer has a thickness from about 1 μm to about 30 μm, about 2 μm to about 20 μm, about 3 μm to about 15 μm, or about 2 μm to about 10 μm. In some embodiments, the Dc layer has a thickness of about 2 μm to about 10 μm, including without limitation, about 2 μm to about 8 μm, about 3 μm to about 7 μm, about 3 μm to about 6 μm, or about 3 μm to about 5 μm, or any range or value therein. In some embodiments, the Dp layer has a thickness of about 5 μm to about 14 μm, including without limitation, about 6 μm to about 12 μm, about 7 μm to about 11 μm, about 8 μm to about 10 μm, or about 8 μm to about 9 μm, or any range or value therein.

### The Imaging Layer

The imaging layer 102 may be positioned between the under-layer and the developer layer. The imaging layer overlying the under-layer may include photosensitive microcapsules 106, which comprise a polymeric shell and a core (or internal phase) encapsulated therein. The internal phase comprises a leuco dye, which imparts color to the microcapsule imaging system (e.g., sheet) upon release under pressure and/or simultaneous or subsequent exposure to heat, certain pH conditions, reactive chemical species, or a developer. Upon release from the microcapsule, the dye (e.g., a leuco dye) undergoes a chemical transformation, transitioning from a colorless state to a color state (e.g., yellow, magenta, cyan, or black).

Depending on the type and desired effect, the various microcapsules disclosed herein may be non-photosensitive, that is, the core is neither softened nor hardened by actinic irradiation, or they may be photosensitive, in which the core is either softened or hardened by actinic irradiation. Additionally, or alternatively, the microcapsules can be pressure-sensitive, that is, when pressure is applied, it crushes the microcapsules, releasing the material inside, e.g., for microcapsules containing a leuco dye and/or a diluent, application of pressure releasing the dye and/or the diluent. The leuco-dye solution then can react with a developer to develop a permanent color for application. The microcapsules can also be photo-hardenable, photo-crosslinkable, or photo-polymerizable, which means they can be hardened, crosslinked or polymerized upon exposure to radiation.

For example, the photosensitive microcapsules 106 may be photo-hardenable, photo-crosslinkable, or photo-polymerizable. In addition to the leuco-dye, the internal phase of the photosensitive microcapsules may further comprise one or more photoinitiators, optionally one or more multifunctional monomers or oligomers, and optionally one or more non-photo-polymerizable reactive diluents. In some embodiments, the photosensitive microcapsules may comprise a polymeric shell and a light-sensitive core which may be photo-hardened by polymerizing or crosslinking the monomers/oligomers included therein. In some embodiments, the core or internal phase comprises a leuco dye, a photoinitiator or sensitizer, and a photohardenable, polymerizable, or crosslinkable monomer or oligomer.

In some embodiments, the core or internal phase comprises a leuco dye. In some embodiments, the leuco dye is one or more of a yellow, cyan, magenta, or black leuco dye. By way of non-limiting example, a representative magenta leuco dye may include PERGASCRIPT® Red I6B (CAS: 50292-95-0, Synamedia-chem); COPIKEM 35 (CAS: 50292-91-6), Blue I-2G and Blue-63 from BASF, Blue 220, Blue 203, Red 500, Red 40 or Black 305 from Yamada, JYDY-1, JYDR-2, JYDR-3, JYDB-1, or JYDB-2 from WuXi Jiayida New Materials, Red-16, O-C6, or O-C8 from Synmedia Chemicals, or ODB-2 from Anyang General Chemicals. Additional suitable examples of leuco dyes are disclosed in, e.g., CHEMISTRY AND APPLICATIONS OF LEUCO DYES (R. Muthyala ed., 1997). Suitable black leuco-dyes include, but are not limited to, ODB-2 from Anyang General Chemical, China, and S-205 and Black 305 from Yamada Chemical, Japan. In another embodiment, the black leuco-dye system is a mixture of leuco-dyes including, for examples, cyan, magenta and yellow leuco-dyes.

In some embodiments, the leuco dye is present in the internal phase at a concentration, by weight, relative to the total weight of the internal phase, of at least about 1 wt. %, at least about 2 wt. %, at least about 3 wt. %, at least about 4 wt. %, at least about 5 wt. %, at least about 6 wt. %, at least about 7 wt. %, at least about 8 wt. %, at least about 9 wt. %, at least about 10 wt. %, at least about 11 wt. %, at least about 12 wt. %, at least about 13 wt. %, at least about 14 wt. %, at least about 15 wt. %, at least about 16 wt. %, at least about 17 wt. %, at least about 18 wt. %, at least about 19 wt. %, at least about 20 wt. %, at least about 25 wt. %, at least about 30 wt. %, at least about 35 wt. %, at least about 40 wt. %, at least about 45 wt. %, at least about 50 wt. %, or any range or value therein between. In some embodiments, the leuco dye is present in the internal phase at a concentration, by weight, relative to the total weight of the internal phase, of no greater than about 50 wt. %, no greater than about 45 wt. %, no greater than about 40 wt. %, no greater than about 35 wt. %, no greater than about 30 wt. %, no greater than about 25 wt. %, or any range or value therein between. In some embodiments, the leuco dye is present in the internal phase at a concentration, by weight, relative to the total weight of the internal phase, of about 1 wt. % to about 50 wt. %, about 5 wt. % to about 40 wt. %, or about 10 wt. % to about 30 wt. %.

The imaging layer suitably may have a thickness of at least about 1 μm, at least about 2 μm, at least about 3 μm, at least about 4 μm, at least about 5 μm, at least about 6 μm, at least about 7 μm, at least about 8 μm, at least about 9 μm, at least about 10 μm, at least about 15 μm, at least about 20 μm, at least about 25 μm, at least about 30 μm, at least about 35 μm, at least about 40 μm, at least about 45 μm, at least about 50 μm, or any range or value therein. In some embodiments, the imaging layer has a thickness from about 1 μm to about 30 μm, about 2 μm to about 25 μm, about 5 μm to about 20 μm, or about 6 μm to about 18 μm, or any range or value therein. In some embodiments, the imaging layer has a thickness of from about 5 μm to about 12 μm, In some embodiments, the imaging layer has a thickness of from about 6 μm to about 18 μm.

### Photo-Polymerizable or Photo-Crosslinkable Multifunctional Monomer or Oligomer

In some embodiments, the core or internal phase of the photosensitive microcapsule comprises a multifunctional monomer or oligomer. In some embodiments, the monomers or oligomers are polymerizable or crosslinkable. In some embodiments, the monomers or oligomers are photo-hardenable. In some embodiments, the monomer or oligomer is selected from multifunctional acrylates and methacylates, multifunctional vinylethers, vinyl esters, allyls or vinylbenzenes, and their oligomers, dendrimers or blends, and combinations thereof. In some embodiments, the monomers or oligomers comprise multifunctional acrylates, which are suitable due to their superior photospeed, compatibility with leuco dyes and developers, and outdoor weatherability. Illustrative monomers and oligomers include, but are not limited to, pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane triacrylate (TMPTA), tris(2-hydroxyethyl) isocyanurate triacrylate, 1,2,4-butane triol trimethacrylate, 1,6-hexanediol diacrylate (HDDA), tripropylene glycol diacrylate (TPGDA), and neopentyl glycol diacrylate (NPGDA), 1,4-cyclohexanediol diacrylate, 1,4-benzenediol dimethacrylate, diethylene triamine tris-methacrylamide, vinyl esters (e.g., divinyl succinate), divinyl adipate, divinyl phthalate, divinyl terephthalate, divinylbenzene, or any combination thereof.

In some embodiments, the one or more monomers or oligomers are present in the internal phase at a concentration by weight, relative to the total weight of the internal phase, of no greater than about 90 wt. %, no greater than about 85 wt. %, no greater than about 80 wt. %, no greater than about 75 wt. %, no greater than about 70 wt. %, no greater than about 65 wt. %, no greater than about 60 wt. %, no greater than about 55 wt. %, no greater than about 50 wt. %, no greater than about 45 wt. %, no greater than about 40 wt. %, no greater than about 35 wt. %, no greater than about 30 wt. %, or any range or value therein between. In some embodiments, the one or more monomers or oligomers are present in the internal phase at a concentration by weight, relative to the total weight of the internal phase, of about 40 wt. % to about 90 wt. %, about 50 wt. % to about 85 wt. %, or about 60 wt. % to about 80 wt. %.

### Photoinitiators

In some embodiments, the core or internal phase of the photosensitive microcapsule comprises one or more photoinitiators. In some embodiments, the one or more photoinitiators comprises one or more borate initiators of the general structure:

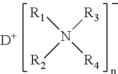

wherein D⁺ is a cationic chromophore, such as a cyanine, squaraine (e.g., squarylium), thiopyrylium, or triarylmethane. In some embodiments, R¹, R², R³, and R⁴ are each independently a substituted or unsubstituted alkyl, arylalkyl, or aryl group. In some embodiments, R¹ is an alkyl or arylalkyl group, and R², R³, and R⁴ are aryl groups. In some embodiments, the one or more photoinitiators comprise one or more of ketocoumarins, benzophenones, thioxanthones, and Norrish Type I, II and III photoinitiators, and combinations thereof. In some embodiments, the photoinitiator is a visible light-sensitive ketocoumarin, cyanine borate or semi-cyanine borate. In some embodiments, the photoinitiator is IR or UV sensitive.

In some embodiments, the one or more photoinitiators are present at a concentration, by weight, relative to the total weight of the internal phase, of greater than or equal to about 0.01 wt. %, greater than or equal to about 0.02 wt. %, greater than or equal to about 0.03 wt. %, greater than or equal to about 0.04 wt. %, greater than or equal to about 0.05 wt. %, greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 1.0 wt. %, greater than or equal to about 2.0 wt. %, greater than or equal to about 3.0 wt. %, greater than or equal to about 4.0 wt. %, greater than or equal to about 5.0 wt. %, greater than or equal to about 10.0 wt. %, or any range or value therein between. In some embodiments, the one or more photoinitiators are present in the internal phase at a concentration, by weight, relative to the total weight of the internal phase, of less than or equal to about 10.0 wt. %, less than or equal to about 5.0 wt. %, less than or equal to about 4.0 wt. %, less than or equal to about 3.0 wt. %, less than or equal to about 2.0 wt. %, less than or equal to about 1.0 wt. %, less than or equal to about 0.5 wt. %, less than or equal to about 0.4 wt. %, less than or equal to about 0.3 wt. %, less than or equal to about 0.2 wt. %, less than or equal to about 0.1 wt. %, less than or equal to about 0.05 wt. %, less than or equal to about 0.04 wt. %, less than or equal to about 0.03 wt. %, less than or equal to about 0.02 wt. %, less than or equal to about 0.01 wt. %, or any range or value therein between. In some embodiments, the one or more photoinitiators are present in the internal phase at a concentration, by weight, relative to the total weight of the internal phase, of about 0.01 wt. % to about 10.0 wt. %, about 0.01 wt. % to about 5.0 wt. %, about 0.01 wt. % to about 1.0 wt. %, about 0.01 wt. % to about 0.5 wt. %, about 0.01 wt. % to about 0.1 wt. %, about 0.01 wt. % to about 0.05 wt. %, about 0.05 wt. % to about 10.0 wt. %, about 0.1 wt. % to about 10.0 wt. %, about 0.1 wt. % to about 10.0 wt. %, about 0.5 wt. % to about 10.0 wt. %, about 1.0 wt. % to about 10.0 wt. %, about 5.0 wt. % to about 10.0 wt. %, about 0.05 wt. % to about 5.0 wt. %, about 0.1 wt. % to about 1.0 wt. %, or any range or value therein.

The imaging layer may comprise one or more types of microcapsules. For instance, the microcapsules may include one or more microcapsules which may be selectively sensitive to white light, UV light, near-IR light, red visible light, green visible light, or blue visible light. In some embodiments, the imaging layer may comprise red-sensitive microcapsules. In some embodiments, the imaging layer may comprise green-sensitive microcapsules. In some embodiments, the imaging layer may comprise blue-sensitive microcapsules. In some embodiments, the imaging layer may comprise one or more of each of red-sensitive, green-sensitive, and blue-sensitive microcapsules, in which case the microcapsule imaging sheet is considered a “full-color” or “panchromatic” imaging sheet.

### First and Second Substrates

In some embodiments, the imaging system comprises a first substrate 101 and a second substrate 105. In some embodiments, the imaging layer, containing the photosensitive microcapsules, is overlaid on to one side of the first substrate. The first substrate may include, for example, any coated paper and/or its pigmented derivatives. In some embodiments, the first substrate is white or transparent. In some embodiments, the first substrate comprises at least one of a polyester (e.g., polyethylene terephthalate (“PET”), polyethylene naphthalate (“PEN”), etc.), a cellulose-based polymer (e.g., cellulose triacetate), a polycarbonate, a polyolefin including cyclic-polyolefin, or combinations, blends, composites, laminates, or copolymers thereof. By way of non-limiting example, the first substrate may be selected from commercially-available films including, but not limited to, HOSTAPHAN® polyester films (Mitsubishi Polyester Film), MELINEX® (DuPont Teijin Films™), and MYLAR® polyester films (DuPont Teijin Films™).

The second substrate, may be overlaid by the low-haze clear developer layer (Dc) on one side. In some embodiments, the developer is coated onto a second substrate. The second substrate may include, for example, any optically clear substrate. In some embodiments, the second substrate comprises at least one of a polyester (e.g., polyethylene terephthalate (“PET”), polyethylene naphthalate (“PEN”), etc.), a cellulose-based polymer (e.g., cellulose triacetate), a polycarbonate, polyolefin including cyclic-polyolefin, or combinations, blends, composites, laminates, or copolymers thereof. By way of non-limiting example, the second substrate may comprise a commercially-available film such as HOSTAPHAN® polyester films (Mitsubishi Polyester Film), MELINEX® (DuPont Teijin Films™), and MYLAR® polyester films (DuPont Teijin Films™).

The substrate(s) may have any suitable thickness. In some embodiments, the first substrate and the second substrate may separately have a thickness of about 3 μm, about 3.5 μm, about 4 μm, about 4.5 μm, about 5 μm, about 10 μm, about 20 μm, about 30 μm, about 40 μm, about 50 μm, about 60 μm, about 70 μm, about 80 μm, about 90 μm, about 100 μm, about 150 μm, about 200 μm, about 250 μm, about 300 μm, about 350 μm, about 400 μm, about 450 μm, about 500 μm, or any range or value therein between. In some embodiments, the thickness of the first substrate is from about 12 μm to about 200 μm, or about 25 μm to about 150 μm. In some embodiments, the thickness of the second substrate is from about 3.5 μm to about 150 μm, or about 10 μm to about 100 μm.

In some embodiments, at least one of the first and the second substrates is an opaque or white substrate. As used herein, the term “opaque” means having a total light transmittance (TLT) of less than 20%, less than 10%, less than 9%, less than 8%, less than 7%, less than 6%, less than 5%, less than 4%, less than 3%, less than 2%, or less than 1%, as measured according to ASTM D1003. The term “white substrate” means a substrate having a whiteness index of at least about 90%, at least about 92%, at least about 95%, at least about 96%, at least about 97%, at least about 98%, at least about 99%, at least about 99.5%, or greater, as measured according to ASTM E313-79. In some embodiments, the first substrate has a whiteness index of higher than 97%, as measured by ASTM E313-79.

In some embodiments, the imaging layer is coated or overlaid on an opaque substrate and the low-haze clear developer layer (Dc) on a clear substrate. In some embodiments, the incipient light passes through the (top) developer layer or the imaging layer and hardens the (bottom) microcapsules. After development, the leuco dye migrates to the developer layer and forms color images therein. The opposite configuration, with top imaging layer and bottom developer layer or the imaging layer layers, may also be used. In some embodiments, the first substrate is opaque. In some embodiments, the second substrate is transparent.

### Under-Layers or Primer Layer

In some embodiments, the microcapsule imaging systems according to the present disclosure may additionally include an under-layer. The under-layer may serve as a primer layer between the first substrate and the imaging layer, or as an adhesive layer or a tie layer to bond the photosensitive imaging layer to the first substrate. In some embodiments, the under-layer is overlaid on to one surface of a first substrate. In some embodiments, the under-layer is a primer layer. In some embodiments, the under-layer is an adhesive layer or a tie layer. Further information regarding exemplary imaging systems containing underlayer structures is set forth in the co-pending application entitled “Improved Imaging Media with Diluent/Solvent Microcapsules and Photosensitive Black Microcapsules In Under-Layer,” filed on the same date (TSW-015), the entire contents of which are incorporated herein by reference, including for the developer structures therein.

### Pressure-Sensitive Microcapsules Containing Solvents, Plasticizers, and Diluents

In some embodiments, the under-layer may include one or more pressure-sensitive microcapsules comprising a solvent, a plasticizer, a diluent, or a combination of any two or more thereof. In some embodiments, the solvent or a diluent is a solvent or a diluent for the leuco-dye in the one or more photosensitive microcapsules in the imaging layer, or a plasticizer for the leuco-dye developer. In some embodiments, the one or more pressure-sensitive microcapsules comprising the solvent, plasticizer, or diluent is non-photosensitive, that is, the core is neither softened nor hardened by actinic irradiation. In some embodiments, the pressure-sensitive microcapsules are photosensitive, in which the core is either softened or hardened by actinic irradiation. In some embodiments, the under-layer comprises the one or more pressure-sensitive microcapsules comprising a solvent, plasticizer or diluent for the leuco-dye developer, alone or in combination with other microcapsules.

In some embodiments, the under-layer comprises one or more microcapsules comprising one or more of a solvent, plasticizer, or diluent at a concentration, measured by dry weight relative to the total dry weight of the under-layer, of at least about 1 wt. %, at least about 2 wt. %, at least about 3 wt. %, at least about 4 wt. %, at least about 5 wt. %, at least about 6 wt. %, at least about 7 wt. %, at least about 8 wt. %, at least about 9 wt. %, at least about 10 wt. %, at least about 11 wt. %, at least about 12 wt. %, at least about 13 wt. %, at least about 14 wt. %, at least about 15 wt. %, at least about 16 wt. %, at least about 17 wt. %, at least about 18 wt. %, at least about 19 wt. %, at least about 20 wt. %, at least about 25 wt. %, at least about 30 wt. %, or any range or value therein between. In some embodiments, the under-layer comprises one or more microcapsules comprising a solvent, plasticizer, or diluent at a concentration, measured by dry weight relative to the total dry weight of the under-layer, of less than about 80 wt. %, less than about 75 wt. %, less than about 70 wt. %, less than about 60 wt. %, less than about 50 wt. %, less than about 45 wt. %, less than about 40 wt. %, less than about 35 wt. %, less than about 30 wt. %, less than about 25 wt. %, less than about 20 wt. %, less than about 15 wt. %, less than about 10 wt. % or any range or value therein between.

In some embodiments, the solvent, plasticizer, or diluent is selected from the group consisting of vegetable oils, epoxidized derivatives of vegetable oils, adipates, phthalates, dihydroxyalkanes, alkyl phosphates, ethers or esters of ethylene glycol, propylene glycol, glycerol, trimethylol propane, and pentaerythritol, and a combination of any two of more thereof, and their epoxided (epoxidized) derivatives. In some embodiments, the diluent comprises an epoxide compound. In some embodiments, the epoxide compound comprises two or more epoxide moieties. In some embodiments, the diluent comprises a di-epoxide or tri-epoxide compound. In some embodiments, the epoxide compound comprises at least one selected from the group consisting of: triglycidyl trimethylolpropane (TMPTGE); epoxided oils including epoxided soybean oil; epoxided castor oil; epoxided linseed oil; epoxided palm oil, dicyclopentadiene diepoxide; cycloaliphatic diepoxide; 3,4-epoxycyclohexylmethyl-3,4-epoxycyclohexanecarboxylate; and 1,2-cyclohexanedicarboxylic acid diglycidyl ester.

In some embodiments, the epoxide groups are not photopolymerizable by the radical-type photoinitiators which may be present in the microcapsules. In some embodiments, the epoxide compounds are configured to react with Lewis acids, phenol groups, or carboxylic groups, and/or the metal complexes, particularly zinc complexes, thereof. Thus, upon pressure development of the exposed image sheet, the epoxides released from the ruptured microcapsules react and crosslink with the Lewis acid, phenol, or carboxylic acid group of the leuco-dye developers.

In some embodiments, the one or more solvent, plasticizer, and diluent are present in the pressure-sensitive microcapsules at a concentration, by weight, relative to the total weight of the internal phase, of no greater than about 40 wt. %, no greater than about 35 wt. %, no greater than about 30 wt. %, no greater than about 25 wt. %, no greater than about 20 wt. %, no greater than about 19 wt. %, no greater than about 18 wt. %, no greater than about 17 wt. %, no greater than about 16 wt. %, no greater than about 15 wt. %, no greater than about 14 wt. %, no greater than about 13 wt. %, no greater than about 12 wt. %, no greater than about 11 wt. %, no greater than about 10 wt. %, no greater than about 9 wt. %, no greater than about 8 wt. %, no greater than about 7 wt. %, no greater than about 6 wt. %, no greater than about 5 wt. %, no greater than about 4 wt. %, no greater than about 3 wt. %, no greater than about 2 wt. %, no greater than about 1 wt. %, or any range or value therein between. In some embodiments, the diluent is present at a concentration of about 3 wt. % to about 20 wt. %, relative to a total weight of the microcapsule. In some embodiments, the diluent is present at a concentration of about 3 wt. % to about 10 wt. %, relative to a total weight of the pressure-sensitive microcapsules.

In some embodiments, the solvent, plasticizer, or diluent has a water solubility of less than or equal to about 5 wt. %. In some embodiments, the solvent, plasticizer, or diluent has a water solubility of less than or equal to about 1 wt. %. The diluents or solvents for the leuco-dyes having a higher boiling point reduces the risk of premature evaporation during storage or transportation. Accordingly the diluents or solvents may have a boiling point of greater than about 100° C., greater than about 120° C., greater than about 150° C., greater than about 170° C., greater than about 200° C., and any range within these values. In some embodiments, the solvent, plasticizer, or diluent has a boiling point greater than about 150° C. In some embodiments, the solvent or diluent has a boiling point greater than about 200° C. A diluent or solvent of low viscosity is highly desirable to facilitate its diffusion to the developer layer and the rate of color development. In some embodiments, the solvent or diluent has a viscosity of less than or equal to about 600 cps at 25° C., determined using a Brookfield viscometer at 100 rpm. In some embodiments, the solvent or diluent has a viscosity of less than about 500 cps, less than about 400 cps, less than about 300 cps, less than about 200 cps, or less than about 100 cps at 25° C., determined using a Brookfield viscometer at 100 rpm. In some embodiments, the solvent or diluent has a viscosity less than 600 cps. In some embodiments, the solvent or diluent has a viscosity less than 150 cps.

### Photo-Hardenable Black Microcapsules

In some embodiments, the under-layer may additionally or alternatively include one or more photo-hardenable black microcapsules comprising a black leuco-dye or a leuco-dye system. In some embodiments, the under-layer comprises both the one or more photo-hardenable black microcapsules and one or more pressure-sensitive microcapsules comprising a solvent, plasticizer or diluent for the leuco-dye developer. In some embodiments, the under-layer comprises only the one or more photo-hardenable black microcapsules. In some embodiments, the one or more photo-hardenable black microcapsules comprise a photo-polymerizable or photo-crosslinkable multifunctional monomer or oligomer and a black leuco-dye or a black leuco-dye system. The black leuco-dye system may include a combination of a black leuco-dyes and a mixture of leuco-dyes (e.g., cyan, magenta, and yellow) fine-tuned to make the color more-like true black after development. In some embodiments, the black leuco-dye system comprises a mixture of two or more leuco-dyes. In some embodiments, the two or more leuco-dyes are selected from a black leuco-dye, a cyan leuco-dye, a magenta leuco-dye, a yellow leuco-dye, a red leuco-dye, a green leuco-dye, and a blue-leuco dye. In some embodiments, the black leuco-dye system comprises a black leuco-dye, and one or more leuco-dyes are selected from a cyan leuco-dye, a magenta leuco-dye, a yellow leuco-dye, a red leuco-dye, a green leuco-dye, and a blue-leuco dye.

In some embodiments, the photo-hardenable black microcapsule comprises the black leuco-dye or a black leuco-dye system at a concentration, relative to the total weight of the photo-hardenable black microcapsule, of about 0.1 wt. % to about 50 wt. %, about 1 wt. % to about 30 wt. %, or about 3 wt. % to about 20 wt. %, or any range or value therein. In some embodiments, the photo-hardenable black microcapsule comprises the black leuco-dye or a black leuco-dye system at a concentration, relative to the total weight of the photo-hardenable black microcapsule, of greater than or equal to about 0.1 wt. %, greater than or equal to about 0.2 wt. %, greater than or equal to about 0.3 wt. %, greater than or equal to about 0.4 wt. %, greater than or equal to about 0.5 wt. %, greater than or equal to about 0.6 wt. %, greater than or equal to about 0.7 wt. %, greater than or equal to about 0.8 wt. %, greater than or equal to about 0.9 wt. %, greater than or equal to about 1 wt. %, greater than or equal to about 2 wt. %, greater than or equal to about 3 wt. %, greater than or equal to about 4 wt. %, greater than or equal to about 5 wt. %, greater than or equal to about 6 wt. %, greater than or equal to about 7 wt. %, greater than or equal to about 8 wt. %, greater than or equal to about 9 wt. %, greater than or equal to about 10 wt. %, greater than or equal to about 15 wt. %, greater than or equal to about 20 wt. %, greater than or equal to about 25 wt. %, or any range or value therein. In some embodiments, the photo-hardenable black microcapsule comprises the black leuco-dye or a black leuco-dye system at a concentration, relative to the total weight of the photo-hardenable black microcapsule, of less than equal to about 60 wt. %, less than or equal to about 55 wt. %, less than or equal to about 50 wt. %, less than or equal to about 45 wt. %, less than or equal to about 40 wt. %, less than or equal to about 35 wt. %, less than or equal to about 30 wt. %, less than or equal to about 25 wt. %, less than or equal to about 20 wt. %, less than or equal to about 15 wt. %, less than or equal to about 10 wt. %, or any range or value therein.

In some embodiments, the photo-hardenable black microcapsule comprises one or more photoinitiators, one or more photo-polymerizable or photo-crosslinkable multifunctional monomers or oligomers, and a black leuco-dye or black leuco-dye system. In some embodiments, the photo-hardenable black microcapsule comprises one or more photoinitiators, one or more multifunctional monomers, and a black leuco-dye or black leuco-dye system. In some embodiments, the photo-hardenable black microcapsule comprises one or more photoinitiators, one or more multifunctional acrylate monomer, and a black leuco-dye or black leuco-dye system.

In some embodiments, the photo-hardenable black microcapsule further comprises one or more photoinitiators. In some embodiments, the photoinitiator is selected from the group consisting of one or more borate initiators. Suitable photoinitiators and their amounts may be as described herein for the imaging layer.

In some embodiments, the photo-hardenable black microcapsule comprises a multifunctional monomer or oligomer. In some embodiments, the monomers or oligomers are polymerizable or crosslinkable. In some embodiments, the monomers or oligomers are photo-hardenable. In some embodiments, the monomer or oligomer is selected from multifunctional acrylates and methacylates, multifunctional vinylethers, multifunctional allyls or vinylbenzenes, and their oligomers, dendrimers or blends, and combinations thereof. Illustrative monomers and oligomers include, but are not limited to, pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane triacrylate (TMPTA), tris(2-hydroxyethyl) isocyanurate triacrylate, 1,2,4-butane triol trimethacrylate, 1,6-hexanediol diacrylate (HDDA), tripropylene glycol diacrylate (TPGDA), and neopentyl glycol diacrylate (NPGDA), 1,4-cyclohexanediol diacrylate, 1,4-benzenediol dimethacrylate, diethylene triamine tris-methacrylamide, vinyl esters (e.g., divinyl succinate), divinyl adipate, divinyl phthalate, divinyl terephthalate, divinylbenzene, or any combination thereof.

In some embodiments, the photo-hardenable black microcapsule further comprises one or more multifunctional acrylate monomers. Multifunctional acrylates are suitable due to their superior photospeed, compatibility with leuco dyes and developers, and outdoor weatherability. Suitable multifunctional acrylate monomers may include, but are not limited to, pentaerythritol triacrylate (PETA-3), pentaerythritol tetra-acrylate (PETA-4), dipentaerythritol hexaacrylate (DPHA), dipentaerythritol pentaacrylate (DPPA), trimethylolpropane triacrylate (TMPTA), 1,6-hexanediol diacrylate (HDDA), tripropylene glycol diacrylate (TPGDA), and neopentyl glycol diacrylate (NPGDA), or a combination of any two or more thereof.

In some embodiments, the one or more monomers or oligomers are present in the internal phase at a concentration by weight, relative to the total weight of the photo-hardenable black microcapsule, of no greater than about 90 wt. %, no greater than about 85 wt. %, no greater than about 80 wt. %, no greater than about 75 wt. %, no greater than about 70 wt. %, no greater than about 65 wt. %, no greater than about 60 wt. %, no greater than about 55 wt. %, no greater than about 50 wt. %, no greater than about 45 wt. %, no greater than about 40 wt. %, no greater than about 35 wt. %, no greater than about 30 wt. %, or any range or value therein between. In some embodiments, the one or more monomers or oligomers are present in the photo-hardenable black microcapsule at a concentration by weight, relative to the total weight of the internal phase, of about 40 wt. % to about 90 wt. %, about 50 wt. % to about 85 wt. %, or about 60 wt. % to about 80 wt. %.

In some embodiments, the spectral sensitivity of the photo-hardenable black microcapsule of the under-layer is different from that of the photosensitive microcapsule in the imaging layer. In some embodiments, the photo-hardenable black microcapsule of the under-layer is sensitive to a wavelength differing from the wavelengths used to expose the photosensitive microcapsules in the imaging layer. In some embodiments, the photo-hardenable black microcapsule is sensitive to a wavelength entirely different from the wavelengths used to expose the photosensitive microcapsules in the imaging layer. In still another embodiment, the black capsule is sensitive to a wavelength (l₄) different from the l₁, l₂, and l₃ (for examples, red, green, and blue light) used to expose the photosensitive microcapsules in the imaging layer. In still another embodiment, the black microcapsule is sensitive to one or two of the l₁, l₂, and l₃ wavelengths. In some embodiments, the photo-hardenable black capsule is sensitive to ultra-violet (UV), infra-red (IR), or yellow light. In some embodiments, the photosensitive microcapsules in the imaging layer is sensitive to red visible light, green visible light, or blue visible light.

One or more of the following benefits are provided by embodiments of the present technology. For example, the rate of color development was significantly improved by the microporosity of the Dp layer via the capillary effect. Additionally, the printing energy efficiency as well as the weatherability or discoloration resistance of the imaging media were significantly improved by the use of the low-haze, clear developer layer. The image media with a microporous developer layer typically showed a significantly faster color development and a higher color saturation than those with a non-microporous developer layer. Not to be bound by theory, it is believed that the that the capillary effect of the microporous layer quickly pulls the unhardened internal phase including the leuco dyes dissolved or dispersed therein into the developer layer, and significantly improves the diffusion rate of the leuco dyes into the developer layer(s) as well as the subsequent rate of reaction between the developers and the leuco-dyes. Additionally, the thickness of each of the developer layers in the imaging system of the present technology is such that a thick Dp layer is used to achieve images with satisfactory color fastness, color saturation and rate of color development, and a thin Dp layer is used to attain the desired discoloration resistance, printing energy efficiency and process window of the media converting and handling process. Furthermore, the media prepared with the two-layer developer sheets exhibits a significantly less degree of out-door discoloration than the media with only the Dp layer, and exhibits a less degree of fading after being aged at 40° C./85% RH for 14 days than that of the media with only the Dp layer. The two-layer developer structure also provides an additional mechanism to achieve better discoloration resistance by distributing the UV absorber (UVA) and optical brighteners (OB) in the two developer layers, such that the media with all the UVA in the Dp layer showed a better out-door discoloration resistance than those media with all the UVA in the Dc layer. In contrast, the media with all the OB in the Dc layer shows a better discoloration resistance than those with all the OB in the Dp layer. In one aspect, which may be combined with any other aspect or embodiment, the present disclosure relates to a method of improving one or more properties of rate of color development, printing energy efficiency rate, weatherability or discoloration resistance, and/or a method of reducing the discoloration after aging while maintaining the color fastness of the developed images.

In some embodiments, the presence of a two-layer developer system comprising separate microporous developer and a low-haze, clear developer layers affords an improvement in the printing energy efficiency, the weatherability or discoloration resistance of the printed media, and the mechanical integrity of the imaging media as measured by 90° and 180° peeling strength between the first and the second substrates, while maintaining the color saturation, rate of color development, and color fastness of the developed images. The efficacy of the optical brighter(s), UV absorber, and antioxidant(s) may be significantly improved by having a higher concentration of the optical brighter in the Dc layer than that in the Dp layer and a higher concentration of the antioxidant and/or UV absorber in the Dp layer than that in the Dc layer. In some embodiments, the De layer comprises of an optical brighter but no UV absorber, and the Dp layer comprises of an UV absorber and/or an antioxidant, but no optical brighter.

### Methods of Preparing an Imaging Sheet

In another aspect, the present technology relates to methods of preparing an imaging sheet, comprising contacting a first substrate with an imaging layer comprising microcapsules comprising one or more photosensitive microcapsules. In some embodiments, the imaging layer is contacted with a microporous developer layer (Dp) according to any of the above-discussed embodiments according to any of the above-discussed embodiments. In some embodiments, the microporous developer layer (Dp) is further contacted with a low-haze, clear developer layer (Dc). In some embodiments, the low-haze, clear developer layer (Dc) is contacted with a second substrate. In some embodiments, the microporous developer layer is overlaid, overcoated, or laminated onto an imaging layer comprising photosensitive microcapsules, which in turn is overlaid on to one surface of a first substrate. In some embodiments, the microporous developer layer (Dp) is deposited between the photosensitive microcapsule layer and the low-haze, clear developer layer (Dc). In some embodiments, the microporous developer layer (Dp) is deposited between the imaging layer and the low-haze, clear developer layer (Dc). In some embodiments, the low-haze, clear developer layer (Dc) layer is deposited between the microporous developer layer (Dp) and a second substrate. In some embodiments, the photosensitive microcapsule imaging layer is overlaid, over-coated or laminated onto the microporous developer layer (Dp) which is overlaid, overcoated or laminated onto the low-haze, clear developer layer (Dc) on a second substrate, and the resultant multilayer coating sheet is laminated with a first substrate which is optionally precoated with an adhesive, a tie layer, a primer layer or an underlayer.

In some embodiments of the methods, the developer in the Dp layer has the same chemical composition as that in the Dc layer. In some embodiments, the developer in the Dp layer has a different chemical composition as that in the Dc layer. In some embodiments, the Dp layer and the Dc layer may have the same chemical composition but different morphology. In some embodiments, the Dp layer and the Dc layer may each have a different type or concentration of leuco-dye developer. In some embodiments, the developer layers may comprise one or more additives such as binders, fillers, antioxidants, optical brighteners, and UV absorbers.

In some embodiments, the method may include an additional step of contacting the first substrate with an under-layer comprising one or more pressure-sensitive microcapsules comprising a solvent, plasticizer, or diluent and/or one or more photo-hardenable black microcapsules according to any of the above-discussed embodiments. In some embodiments, the under-layer then is coated with an imaging layer comprising microcapsules comprising one or more photosensitive microcapsules. In some embodiments, the under-layer may comprise one or more solvent, plasticizer, or diluent microcapsule comprising a polymeric shell; and an internal phase comprising a solvent or a diluent for the leuco-dye in the one or more photosensitive microcapsules, or a plasticizer for the developer. In some embodiments, the microcapsules in the under-layer comprise solvent microcapsules, diluent microcapsules, plasticizer microcapsules or any combination thereof. In some embodiments, the under-layer may comprise one or more photo-hardenable black microcapsules. In some embodiments, the one or more photo-hardenable black microcapsules comprises a photo-polymerizable or photo-crosslinkable multifunctional monomer or oligomer and a black leuco-dye or a black leuco-dye system. In some embodiments, an imaging layer may include photosensitive microcapsules for a microcapsule imaging system, the photosensitive microcapsule comprising a leuco-dye and a multifunctional photo-polymerizable or crosslinkable monomer or oligomer. In some embodiments, the microcapsules in the imaging layer may comprise a polymeric shell and an internal phase comprising a leuco dye; a photoinitiator; and a polymerizable or crosslinkable monomer or oligomer.

In some embodiments, the method of producing an imaging sheet includes contacting the imaging layer-coated first substrate with a microporous developer layer to produce a microporous developer (Dp) coated imaging layer coated first substrate (Dp/imaging layer/first substrate). In some embodiments, the Dp/imaging layer/first substrate is contacted with low-haze, clear developer layer, which is then contacted with a second substrate to produce an imaging system or sheet. In some embodiments, the low-haze, clear developer layer (Dc) is coated onto a second substrate to produce a Dc-coated second substrate before being placed into contact with a Dp layer to produce a microporous developer coated low-haze, clear developer layer coated second substrate (Dp/Dc/second substrate). In some embodiments, the Dp/Dc/second substrate and the imaging layer coated first substrate (imaging layer/first substrate) are contacted with one another, such that the Dp layer contacts the imaging layer. In some embodiments, the Dc-coated second substrate and the Dp/imaging layer/first substrate are contacted with one another, such that the microporous developer layer contacts the imaging layer. In some embodiments, the imaging layer is overlaid or overcoated on the Dp/Dc/second substrate, and the resultant imaging layer/Dp/Dc/second substrate is laminated with the first substrate, optionally with an adhesive layer, a tie layer, a primer, or an under-layer to form the imaging recording medium. In some embodiments, an under-layer may be positioned between the first substrate and the imaging layer. In some embodiments, an optically clear primer or durable layer may be positioned between the second substrate and the low-haze, clear developer layer.

### Methods of Using Microcapsules and Imaging Sheets

In another aspect, which may be combined with any other aspect or embodiment, the present disclosure relates to methods of using microcapsules according to any of the above-discussed embodiments. In another aspect, which may be combined with any other aspect or embodiment, the present disclosure relates to methods of using imaging sheets according to any of the above-discussed embodiments.

For example, in some embodiments, a method of imaging or printing includes image-wise exposing an imaging sheet comprising a microcapsule according to any of the above-discussed embodiments to heat, pressure, or radiation, wherein the exposing is sufficient to selectively release by pressure and/or heat the microcapsule's internal phase comprising a leuco dye and/or a non-photopolymerizable diluent configured to react with a leuco-dye developer from the microporous developer layer (Dp) and/or a low-haze, clear developer layer (Dc) to produce a color image.

In some embodiments, the present disclosure relates to methods of adjusting (e.g., so as to improve) one or more properties of an imaging sheet, including adding the microporous developer layer (Dp) and/or a low-haze, clear developer layer (Dc) of the present disclosure to an imaging sheet. In some embodiments, the one or more properties comprises one or more of Dₘₐₓ; fresh Dₘₐₓ; Dₘₐₓ, t; Dₘᵢₙ; image resolution; edge sharpness; temperature latitude; dynamic range; discoloration (yellowing) resistance; structure integrity of the imaging media, and color fastness of the developed image.

For the purpose of clarity and a concise description, features may be described herein as part of the same or separate aspects or embodiments of the present technology. It will be appreciated by the skilled person that the scope of the present technology may include embodiments having combinations of all or some of the features described herein as part of the same or separate embodiments.

The inventions are explained in more detail in the following, non-limiting examples. The examples are provided to illustrate coating processes applicable to making the particles of the present technology. These examples are not intended to limit the scope of the present technology. All parts and percentages are by weight unless otherwise indicated.

### EXAMPLES

### Materials

TABLE 1

| Tradename | Ingredient |
|---|---|
| Acrysol TT-615 | HASE thickener from Dow corp. |
| Zemac E60 | Ethylene maleic anhydride copolymer from Aurorium Corp. |
| Versa TL502 | Sulfonated polystyrene from Nouryon Corp. |
| XIRAN 1000P | Random styrene maleic anhydride (SMA) copolymers Aurorium Corp. |
| Poval ™ 05-88 | Polyvinyl alcohol from Kuraray Crop. |
| Poval ™ 44-88 | Polyvinyl alcohol from Kuraray Crop. |
| TAMOL 731DP | A hydrophobic copolymer dispersant from Dow Corp. |
| Nipacide BIT 10W | Biocide based on BIT from Clariant Corp. |
| Aerosol OT | Sodium bis (2-ethylhexyl) sulfosuccinate surfactant from Cytec Corp. |
| Plurafac ® LF305 | Surfactant from BASF. |
| Triton X114 | Surfactant from Dow. |
| ABEX 18S | Emulsifier from Solvay Corp. |
| Silwet L-7001 | Silicone surfactant from Momentive Performance Materials |
| Silwet L-7604 | Silicone surfactant from Momentive Performance Materials |
| Joncryl 7124 | Acrylic latex emulsion from BASF. |
| GPI-15 | PMMA spacer particles from Guidewin Corp. |
| Eastman AQ ™ 55S | Sulfopolyester from Eastman Chemical |
| Hycar 26-1199 | Acrylic latex emulsion from The Lubrizol Corporation |
| P-208-M1 | Acrylic latex emulsion from Chang Chun Group Crop. |
| Primal AC-261T | Acrylic latex emulsion from Dow. |
| ROPAQUE ™ | Opaque polymeric pigment from Dow. |
| ULTRA-E | |
| R-054 | Color developer (powder) for pressure sensitive paper from Sanko Corp. |
| BR-054 | Color developer (dispersion) for pressure sensitive paper from Sanko Corp. |
| RD9870A | Color developer (dispersion) for pressure sensitive paper from Richful Corp. |
| Resin Developer | Color developer (dispersion) from Hebi Yidafeng Ind. Co. Ltd, China |
| H-503 | |
| IRGANOX 1035 | Primary phenolic antioxidant and heat stabilizer from BASF |
| Tinuvin 400DW | An aqueous triazine-based UV absorber dispersion from BASF. |
| DOUBLETEX | Optical brightener from Taiwan Doubletex Corporation |
| CBS-1 | |
| Aerodisp W7512S | An aqueous dispersion of fumed silica from Evonik Crop. |
| CAB-O- | An aqueous dispersion of fumed silica from Cabot Corp. |
| SPERSE ® 1015A | |
| TiO2 dispersion | Water-based dispersion of TiO2 from Taiwan Nanotechnology |
| | Corporation. |
| PCC dispersion | Water-based dispersion of CaCO3 from Taiwan Nanotechnology |
| | Corporation. |
| Desmodur ® N 100 | Polyisocyanate from Covestro Corp. |
| Cymel 385 | Methylated melamine resin with a low degree of alkylation from Allnex Corp. |

### Example 1—Preparation of Photosensitive Microcapsules

301.98 parts of a 10.37 wt. % aqueous solution of Versa TL502, 182.67 parts of a 10 wt. % aqueous solution of ZeMac E60, 76.55 parts of a 15 wt. % solution of XIRAN 1000P in DI water, 10.44 parts of a 10 wt. % solution of ABEX-18S in DI water, 10.44 parts of a 5 wt. % solution of Na₂SO₄ in DI water, and 1043.84 parts of DI water were mixed thoroughly at 500 rpm. The pH was then adjusted to 6.0 to form an aqueous phase of 1043.84 parts. 600.00 parts of the internal (oil) phase as shown in Table 2 were emulsified into the 1043.84 parts of the aqueous phase in a dark room to form a pre-emulsion of the internal phase. The thus formed pre-emulsion was pumped through a 30 mm SPG membrane twice followed by an 8 mm SPG membrane twice.

TABLE 2
Internal Phase Compositions of The Photosensitive Microcapsules

| | Example 1a | Example 1b | Example 1c |
|---|---|---|---|
| | Cyan | Magenta | Yellow |
| | Capsule | Capsule | Capsule |
| | Red- | Green- | Blue- |
| Ingredients | sensitive | sensitive | sensitive |
| TMPTA (Trimethylolpropane triacrylate) | 473.62 | 429.38 | 447.94 |
| DM186 (Acrylated Epoxidized Soybean Oil) | 24.93 | 22.60 | 23.58 |
| DIDMA (2,6-diisopropyl-N,N-dimethylaniline) | 14.96 | 13.56 | 14.15 |
| Irganox ® 1035 | 0.75 | 2.71 | 0.71 |
| Yellow Leuco Dye (CAS: Hexylfluorescein | — | — | 63.65 |
| Dimethyl Ether from Aether industries, India) | | | |
| Yellow Leuco Dye (CAS: 144190-25-0 from | — | — | 7.07 |
| Synmedia-chem) | | | |
| Magenta Leuco Dye (CAS: 50292-95-0 from | — | 90.40 | — |
| Synmedia-chem) | | | |
| Cyan Leuco Dye (CAS: 114090-18-5 from | 39.88 | — | — |
| NAGASE) | | | |
| Black Leuco Dye (CAS: 89331-94-2 from | 0.50 | 0.45 | — |
| Angene Chemical) | | | |
| EMTBS (Ethoxy-Mercaptobenzothiazole | 3.49 | 3.16 | 3.77 |
| disulfide from Aether industries, India) | | | |
| Tetrabutylammonium (sec- | 1.00 | 0.90 | 0.94 |
| Butyl)triphenylborate | | | |
| Red-sensitive photoinitiator | 1.00 | — | — |
| 1-Heptyl-2-[5-(1-heptyl-3,3-dimethyl-1,3- | | | |
| dihydro-2H-indol-2-ylidene)-penta-1,3-dienyl]- | | | |
| 3,3dimethyl-3H-indolium(sec- | | | |
| Butyl(triphenylborate) | | | |
| Green-sensitive photoinitiator | — | 0.68 | — |
| 1-Heptyl-2-[3-(1heptyl-3,3-dimethyl-1,3- | | | |
| dihydro-indol-2-ylidene)-propenyl]- | | | |
| 3,3dimethyl-3H-indolium(sec- | | | |
| Butyl)triphenylborate | | | |
| Blue-sensitive photoinitiator | — | — | 0.47 |
| 3-Ethyl-2-[(1-Ethyl-3,3-dimethyl-1,3-dihydro- | | | |
| 2H-indol-2-ylidene)-methyl]benzothiazolium | | | |
| (sec-Butyl)triphenylborate | | | |
| Desmodur ® N 100 | 39.88 | 36.16 | 37.72 |

9.91 parts of a 10 wt. % solution of Abex 18S in DI water were added to 1350.00 parts of the emulsion thus obtained and stirred at 500 rpm for 10 min. 66.04 parts of a 10 wt. % ZeMac E60 solution in DI water, and 3.32 parts of diethylene triamine (DETA) with the pH preadjusted to 6.0 by a 5% H₃PO₄ solution in DI water, were added to the emulsion. The pH of the resultant emulsion was adjusted to 6.0 and allowed to react at 25° C. for 15 h at 500 rpm. The temperature was raised to 40° C., and upon reaching 40° C., the pH of the emulsion was adjusted to 6.0 and a mixture of 97.50 parts of Cymel 385 and 182.00 parts of DI water were added, and the emulsion was allowed to react at 40° C. for an hour at 700 rpm. The temperature was raised to 70° C., and after 2 h of reaction, 21.35 parts of Na₂SO₄ and 96.09 parts of DI water were added, followed by 13.00 parts of Cymel 385 and 78.00 parts of DI water, and the reaction was continued for 1 h. 30.37 parts of Urea and 91.10 parts of DI water were added and allowed to react at 70° C. for 1 h at 700 rpm to form a slurry of photosensitive microcapsules. The microcapsule slurry was diluted to about 15 wt. % with DI water, and the pH was adjusted to 9.0. The diluted slurry was filtered with a 500-mesh sieve and centrifuged twice to remove the aqueous phase.

All of the microcapsules prepared in Examples 1 were purified by the same dilution, filtration centrifuge procedure. The resultant microcapsules were analyzed for particle size distribution by a Laser Diffraction Particle Size Analyzer LA-960V2 from HORIBA., and the particle size was summarized in Table 3.

TABLE 3
Particle Size

| | | Particle size | Particle size |
|---|---|---|---|
| | | (D₅₀) (before | (D₅₀) (after |
| Example | Description | purification) | purification) |
| Example-1a | Cyan capsule | 7.42 mm | 7.22 mm |
| Example-1b | Magenta capsule | 7.25 mm | 7.11 mm |
| Example-1c | Yellow capsule | 7.80 mm | 7.91 mm |

### Example 2: Preparation of the Primer Layer

The composition of primer layer as shown in Table 4 was coated on a 50 mm white PET (Melinex 339 from DuPont Teijin Film) by a wire bar and dried in an 80° C. oven for 10 min with a target dry thickness of 1.5 mm.

TABLE 4
Primer Layer

| Ingredient | Dry parts |
|---|---|
| Primal AC-261T | 25.65 |
| ROPAQUE ™ Ultra-E | 20.00 |
| PCC, CaCO₃ Dispersion | 20.00 |
| TiO₂ Dispersion | 30.00 |
| Nipacide BIT 10W | 0.05 |
| Acrysol TT615 | 1.20 |
| Silwet L7604 | 0.05 |
| Aerosol OT | 0.40 |
| Tirton X114 | 0.05 |
| Tamol 731DP | 2.60 |

### Example 3: Preparation of the Photosensitive Microcapsule Layer

The composition of the full-color photosensitive microcapsule layer as shown in Table 5 was over-coated on the primer layer in a dark room by a doctor blade and dried in an 80° C. oven for 10 min with a target dry thickness of 9.0 mm. The total thickness of the photosensitive microcapsule sheets is about 60.5 mm.

TABLE 5
Full-Color Photosensitive Microcapsule Layer

| Ingredient | Dry parts |
|---|---|
| Cyan Microcapsule from Example 1a | 33.17 |
| Magenta Microcapsule from Example 1b | 33.17 |
| Yellow Microcapsule from Example 1c | 33.17 |
| GPI-15 | 0.50 |
| PCC, CaCO₃ dispersion | 2.00 |
| TiO₂ dispersion | 3.75 |
| Acrysol TT-615 | 0.31 |
| Nipacide BIT 10W | 0.05 |
| Aerosol OT | 0.26 |
| Triton X114 | 0.01 |
| Plurafac ® LF305 | 0.30 |
| Tamol 731 DP | 5.00 |
| Silwet L-7001 | 0.20 |
| Silwet L-7604 | 0.20 |
| Joncryl 7124 | 10.00 |
| AQ55S | 8.00 |

### Example 4: Preparation of a Single-Layer Dp

The composition of Dp layer as shown in Table 6 was coated on a 23 μm clear PET with a wire bar with a target dry thickness of 4˜14 μm. The drying temperature was controlled at 50° C., slightly below the minimum film formation temperature of the developer dispersion, for 10 min to obtain a haze developer layer with a haze >65% as measured by a YH1600 Haze Meter from 3nh Technology, China.

TABLE 6
Composition of Single-layer Dp

| Ingredient | Dry parts |
|---|---|
| Color Developer RD9870A | 51.00 |
| Color Developer H-503 | 34.68 |
| Hycar 26-1199 | 8.49 |
| CAB-O-SPERSE ® 1015A | 2.68 |
| Poval 44-88 | 0.80 |
| Poval 05-88 | 1.96 |
| Aerosol OT | 0.39 |

### Example 5: Preparation of Full-Color Imaging Media with Single-Layer Dp

The photosensitive microcapsule/primer sheets of Example 3 were laminated onto the single-layer Dp developer sheets as prepared in Example 4, with a Tamerica roll laminator TCC2700 with the roller temperature, pressure, and lamination speed set at 60° C., 3.621 Kgf/170 mm and 0.368 m/min, respectively to form the full-color imaging media with various thickness of the Dp layer (Examples 5-1 to 5-6) with a haze level of ≥65% as measured by a YH1600 Haze Meter. All the procedures were conducted in a dark room. The thus prepared full-color imaging media were developed by a high-pressure development fixture. The black Dₘₐₓ developed immediately after the pressure development (fKDmax) and after aged in a 40° C./85% RH chamber for 3 days (KDmax,_{3d}) and 7 days (KDmax,_{7d}) as measured by an exact from X-Rite, MI, USA, were summarized in Table 7. Additionally, listed are (a) the 180° peeling strength of the unexposed full-color imaging media as measured by an Instron 3367 from Universal Testing Systems at a speed of 30 mm/min; and (b) D (Y.I)_{3d}, the increase in yellow index (ASTM E313) of the developer sheets after conditioned in a Q-SUN chamber at 0.68 W/m² and 63° C. for 3 days. All the developer sheets were pre-calendered against a release PET film at 120° C. before the Q-SUN weathering tests to minimize the light scattering effect.

TABLE 7
Full-Color Media with 1-Layer Dp

| | Dp | Peeling | Black Color Density (KDmax) | | | |
|---|---|---|---|---|---|---|
| | Thickness | force | | 3-day | 7-day | D(YI),_{3 d} |
| Example | (mm) | (gf/inch) | Fresh | aging | aging | Q-SUN |
| 5-1 | 4.0 | 5.03 | 0.50 | 0.86 | 0.82 | 21.4 |
| 5-2 | 6.0 | 8.21 | 0.52 | 1.07 | 1.02 | 22.2 |
| 5-3 | 8.0 | 10.15 | 0.53 | 1.06 | 1.07 | 31.9 |
| 5-4 | 10.0 | 10.59 | 0.54 | 1.06 | 1.08 | 32.3 |
| 5-5 | 12.0 | 11.41 | 0.55 | 0.97 | 1.06 | 37.3 |
| 5-6 | 14.0 | 13.48 | 0.55 | 0.99 | 1.07 | 40.2 |

It is evident from Table 7 that the KDmax of the media increases first but levels off after the Dp thickness is higher than about 8-10 mm. It appears that the amount of dye developers present in the ≥8-10 mm single-layer Dp is enough to fully react with the leuco-dyes released from the about 9 mm microcapsule layer as prepared in Example 3.

It can also be seen clearly from Table 7 that both the degree of discoloration in the Dmin area, and the peeling forces increase as the thickness of the Dp layer increases. A minimum peeling strength (≥about 10˜15gf/in) of the media is typically needed to ensure a high yield rate for the subsequent converting, slitting/cutting, storage, transportation, and handling processes of the imaging media. Not to be bound by theory, it is believed that to ensure a satisfactory adhesion with an about 9 mm microcapsule layer containing therein a high loading (>75 wt. %, dry) of about 7 to about 7.5 mm photosensitive microcapsules, a thicker developer layer is required to compensate for the surface roughness of the capsule layer and allow a sufficient contact area between the two layers. A thicker developer layer tends to result in a poorer yellowing resistance since most film-forming commercially available leuco-dye developers comprise a phenol or salicylate derivative which can be easily thermos- or photo-oxidized and the Dmin areas turn yellow or even brown upon aging or weathering.

### Example 6: Low-Haze Developer Layer (Dc) and Two-Layer (Dp/Dc) Developers

The low-haze developer (Dc) compositions as shown in Table 8A were adjusted to 35 wt. % fluids and coated on a 23 mm clear PET film with a wire bar and dried in a 90° C. oven with a target dry thickness of about 2 to about 6 mm.

TABLE 8A
Composition of Low-Haze Developer layer (Dc)

| | Examples | Example | Example | Example |
|---|---|---|---|---|
| Ingredient (Dry Wt. %) | 6-1~6-6 | 6-7 | 6-8 | 6-9 |
| Latex binder, P208-M1 | 97.88 | 87.51 | 77.13 | 66.76 |
| Developer, R-054 | 0.00 | 10.00 | 20.00 | 30.00 |
| Dispersion (Table 8B) | | | | |
| Doubletex CBS-1 | 1.00 | 1.00 | 1.00 | 1.00 |
| Aerodisp W7512S | 1.00 | 1.00 | 1.00 | 1.00 |
| Aerosol OT | 0.02 | 0.07 | 0.12 | 0.17 |
| Poval 05-88 | 0.10 | 0.40 | 0.70 | 1.00 |
| Triton X114 | 0.00 | 0.03 | 0.05 | 0.08 |

The Developer (R-054) dispersion used in the Dc layer of Examples 6-7, 6-8 and 6-9 was prepared by homogenizing the composition as shown in Table 8B followed by stripping off the solvent, (ethyl acetate). The average particle size is 0.131 mm, 0.232 mm and 0.394 mm for D10, D50, D90, respectively as measured by a Horiba LA-960V2 laser particle size analyzer. All the dried Dc layers in Example 6 showed a haze of ≤10% as measured by a YH1600 Haze Meter.

TABLE 8B
Composition of Developer Dispersion

| Ingredients | Parts |
|---|---|
| R-054 in ethyl acetate (50% solid) | 100.00 |
| Aerosol OT | 0.50 |
| Triton X114 | 0.25 |
| Poval 05-88 | 3.00 |
| Water | 92.39 |

A Dp layer with the same composition as described in Example 4 and Table 6 was then overcoated on the Dc layer with a wire bar and dried in a 50° C. oven with a target dry thickness of about 6 to about 10 mm. As it can be seen from Examples 6-7 to 6-9 in Table 8A that the Dc layer comprises a significantly lower concentration (10-30 wt. %) of dye developers as compared with that (85.7 wt. %) in the Dp layer as shown in Example 4, Table 6.

The two-layer developer sheets were then laminated with the photosensitive microcapsule/primer sheets of Example 3 with the same procedure as described in Example 5. The peeling force, black color density (KDmax) and 3-day Q-Sun discoloration, D (Y.I) 3d of the full-color media (Examples 6-1 to 6-9) as well as the comparative media (Examples 5-3 to 5-6) are summarized in Table 9.

It is evident from Table 9 that compared with the media prepared with single-layer (Dp) developer sheet (Examples 5-3 to 5-6), most of the imaging media prepared with the two-layer (Dp/Dc) developer sheet (Examples 6-1 to 6-9) showed an improved peeling force and a higher black color density (KDmax) even for media with a lower coverage (g/m²) of dye developer(s). Moreover, all the media prepared with two-layer (Dp/Dc) developer sheets showed a significantly lower degree of discoloration D (Y.I) 3a than those media prepared with a single-layer (Dp) developer sheet comprising a similar developer coverage (e.g., Example 5-3 vs. Examples 6-1, 6-4, and 6-6 to 6-9; and Example 5-4 vs. Examples 6-3 and 6-5).

TABLE 9
Effect of the Dp/Dc two-layer Developer

| | | | | | Total Dye | | | | | |
|---|---|---|---|---|---|---|---|---|---|---|
| | | | R-054 | | Developer | | Black Color Density | | | |
| | | Dc | in Dc | Dp | in the | Peeling | (KDmax) | | | |
| | | Thickness | (Dry | Thickness | Media | Force | | 3-day | 14-day | D(YI),_{3 d} |
| Example | | (mm) | Wt. %) | (mm) | (g/m²) | (gf/in) | Fresh | aging | aging | Q-SUN |
| 5-3 | Comparative | 0.0 | N/A | 8.0 | 6.94 | 10.15 | 0.53 | 1.06 | 1.05 | 31.9 |
| 5-4 | Media with | 0.0 | N/A | 10.0 | 8.67 | 10.59 | 0.54 | 1.06 | 1.08 | 32.3 |
| 5-5 | 1-Layer | 0.0 | N/A | 12.0 | 10.40 | 11.41 | 0.55 | 0.97 | 1.07 | 37.3 |
| 5-6 | Developer | 0.0 | N/A | 14.0 | 12.14 | 13.48 | 0.55 | 0.99 | 1.12 | 40.2 |
| 6-1 | Media With | 2.0 | 0% | 8.0 | 6.94 | 11.23 | 0.55 | 1.24 | 1.21 | 22.0 |
| 6-2 | Two-Layer | 4.0 | 0% | 6.0 | 5.20 | 11.20 | 0.53 | 1.12 | 1.04 | 17.3 |
| 6-3 | Developer | 2.0 | 0% | 10.0 | 8.67 | 11.26 | 0.56 | 1.19 | 1.17 | 31.6 |
| 6-4 | | 4.0 | 0% | 8.0 | 6.94 | 11.50 | 0.54 | 1.16 | 1.16 | 17.9 |
| 6-5 | | 4.0 | 0% | 10.0 | 8.67 | 13.89 | 0.55 | 1.15 | 1.17 | 28.9 |
| 6-6 | | 6.0 | 0% | 8.0 | 6.94 | 11.56 | 0.58 | 1.19 | 1.18 | 20.1 |
| 6-7 | | 4.0 | 10% | 7.5 | 6.90 | 11.48 | 0.53 | 1.14 | 1.16 | 17.2 |
| 6-8 | | 4.0 | 20% | 7.1 | 6.96 | 11.60 | 0.56 | 1.15 | 1.18 | 17.1 |
| 6-9 | | 4.0 | 30% | 6.6 | 6.92 | 11.68 | 0.57 | 1.17 | 1.18 | 16.7 |

The effect of the two-layer (Dp/Dc) developer structure on the improvements in the black color density of the developed images with a significantly lower coverage of dye developers in the image media is further illustrated in Table 10. Developer sheets of Comparative 1-layer Dp (Example 5-5) and two-layer Dp/Dc (Examples 6-4, 6-7, 6-8 and 6-9) were prepared and calendered at an applied force, speed and setting temperature of 3.621 Kgf/170 mm, 0.368 m/min, and 40-90° C., respectively with a 50 μm release PET film as the cover sheet. Their 14-day KDmax and haze value (Hz %) as measured with a YH1600 Haze Meter (from 3nh, China) are summarized in Table 10.

TABLE 10
Effect of Dc on Hz % after Calendering

| Example | 5-5 | 6-4 | 6-7 | 6-8 | 6-9 |
|---|---|---|---|---|---|
| Dc (μm) | 0 | 4.0 | 4.0 | 4.0 | 4.0 |
| Dp (μm) | 12.0 | 8.0 | 7.5 | 7.1 | 6.6 |
| Total Thickness of | 12.0 | 12.0 | 11.5 | 11.1 | 10.6 |
| Developer layer (mm) | | | | | |
| Total Coverage of Dye | 10.4 | 6.94 | 6.9 | 6.96 | 6.92 |
| Developer (g/m²) | | | | | |
| KDmax, 14 days | 1.07 | 1.16 | 1.16 | 1.18 | 1.18 |
| Calender Temperature | Hz % | | | | |
| Before calendering | 72.3 | 72.2 | 70.3 | 70.3 | 69.5 |
| 40° C. | 63.1 | 61.5 | 60.5 | 60.2 | 58.8 |
| 50° C. | 57.9 | 53.7 | 49.5 | 49.4 | 49.4 |
| 60° C. | 23.0 | 21.0 | 20.6 | 21.6 | 20.0 |
| 70° C. | 22.1 | 19.5 | 19.0 | 18.5 | 15.8 |
| 80° C. | 21.2 | 14.6 | 15.1 | 14.2 | 13.4 |
| 90° C. | 19.1 | 12.8 | 12.6 | 12.0 | 11.8 |

It is evident that the developer sheets comprising the low-haze Dc layer showed a significant reduction in the haze value of the developer sheets even at a lower calendering temperature. Not to be bound by theory, it is believed that an image layer of a lower haze reduced the degree of light scattering and allowed the color images to be better seen or detected, and resulted in a higher KDmax, even though the two-layer developer sheets (Examples 6-4, and 6-7 to 6-9) contain a lower dye developer coverage than that of the single-layer developer sheet (Comparative Example 5-4).

### Example 7: Two-Layer (Dp/Dc) Developers with Various Concentrations of UV

“\* MERGEFORMAT\* MERGEFORMAT Absorber (UVA) and Optical Brightener (OB) in Each Layer.

Dc layers of a composition (in dry wt. %) comprising 10.0% of developer R-054, 1% of Aerodisp W7512S, 0.07% of Aerosol OT, 0.4% of PVA Poval 05-88, 0.025% of Triton X-100, about 85.01 to about 88.01% of P208-M1 as the binder, about 0.0 to about 1.0% of Doubletex CBS-1 as the optical brightener, and about 0 to about 2.5% of Tinuvin 400DW as the UV absorber were coated and dried on a 23 mm clear PET film with a target dry thickness of 4.0 mm. The same R-054 dispersion of Example 6 (Table 8B) was used for the preparation of all the Dc layers of Example 7.

Dp layers of a composition (in dry wt. %) comprising 50.46% of developer RD9870, 34.31% of developer H-503, 2.65% of CAB-O-SPERSE® 1015A, 0.79% of Poval 44-88, 3.0% of Poval 05-88, 0.39% of Aerosol OT, 6.65˜8.4% of Hycar 26-1199 as the binder, 0˜0.5% of Doubletex CBS-1, and 0.0˜1.25% of Tinuvin 400DW were coated either directly on a 23 mm clear PET (Examples 7-1) with a target dry thickness of 8.5 mm, or overcoated on the Dc layers (Examples 7-2 to 7-10) with a target dry thickness of 8.0 mm.

The developer sheets thus prepared were laminated with the microcapsule sheets as prepared in Example 3 to form imaging media comprising various concentration of UV absorber and optical brightener in the Dc and Dp layers. The results of their black color density (KDmax) and the discoloration resistance as indicated by the changes in the yellow index, D (Y.I) after aging in a Q-SUN or 40° C./85% RH chamber are shown in Table 11.

TABLE 11
Composition of Developer Sheets

| | | Example 7 | | | | |
|---|---|---|---|---|---|---|
| | | Media with | | | | |
| | | 1-Layer | | | | |
| | | Developer | Media with Two-Layer Developer | | | |
| Ingredient (dry wt. % in | | Example 7-1 | Example | Example | Example | Example |
| the Dc or Dp layer) | | (Comparative) | 7-2 | 7-3 | 7-4 | 7-5 |
| Dc | P208-M1 | 0.0 | 85.01 | 87.51 | 86.01 | 88.51 |
| layer | Doubletex | 0.0 | 1.00 | 1.00 | 0.00 | 0.00 |
| | CBS-1 | | | | | |
| | Tinuvin 400DW | 0.0 | 2.50 | 0.00 | 2.50 | 0.00 |
| | Thickness (mm) | 0.0 | 4.0 | 4.0 | 4.0 | 4.0 |
| Dp | Hycar 26-1199 | 6.76 | 8.40 | 7.15 | 7.90 | 6.65 |
| layer | Doubletex | 0.47 | 0.00 | 0.00 | 0.50 | 0.50 |
| | CBS-1 | | | | | |
| | Tinuvin 400DW | 1.18 | 0.00 | 1.25 | 0.00 | 1.25 |
| | Thickness (mm) | 8.5 | 8.0 | 8.0 | 8.0 | 8.0 |
| Total Thickness of | | 8.5 | 12.0 | 12.0 | 12.0 | 12.0 |
| Developer Layers (mm) | | | | | | |
| Total OB used (g/m2) | | 0.04 | 0.04 | 0.04 | 0.04 | 0.04 |
| OB in Dc (g/m2) | | 0.00 | 0.04 | 0.04 | 0.00 | 0.00 |
| OB in Dp (g/m2) | | 0.04 | 0.00 | 0.00 | 0.04 | 0.04 |
| Total UVA used (g/m2) | | 0.10 | 0.10 | 0.10 | 0.10 | 0.10 |
| UVA in Dc (g/m2) | | 0.00 | 0.10 | 0.00 | 0.10 | 0.00 |
| UVA in Dp (g/m2) | | 0.10 | 0.00 | 0.10 | 0.00 | 0.10 |
| Black | Fresh | 0.52 | 0.56 | 0.55 | 0.51 | 0.54 |
| Density | 3 days | 1.10 | 1.15 | 1.14 | 1.13 | 1.17 |
| (KDmax) | @40° C./85% RH | | | | | |
| | 14 days | 1.04 | 1.19 | 1.17 | 1.16 | 1.18 |
| | @40° C./85% RH | | | | | |
| Yellow | YI, Fresh | 2.4 | 2.4 | 2.5 | 2.4 | 2.3 |
| Index | Δ(YI)_{3 d}, Q-SUN | 35.6 | 19.5 | 18.1 | 21.1 | 19.8 |
| (YI) | Δ(YI)_{3 d} | 0.5 | 0.1 | 0.0 | 0.1 | 0.0 |
| | @40° C./85% RH | | | | | |

| | | Media with Two-Layer Developer | | | | |
|---|---|---|---|---|---|---|
| Ingredient (dry wt. % in the | | Example | Example | Example | Example | Example |
| Dc or Dp layer) | | 7-6 | 7-7 | 7-8 | 7-9 | 7-10 |
| Dc | P208-M1 | 86.76 | 86.26 | 87.26 | 85.51 | 88.01 |
| layer | Doubletex CBS-1 | 0.50 | 1.00 | 0.00 | 0.50 | 0.50 |
| | Tinuvin 400DW | 1.25 | 1.25 | 1.25 | 2.50 | 0.00 |
| | Thickness (mm) | 4.0 | 4.0 | 4.0 | 4.0 | 4.0 |
| Dp | Hycar 26-1199 | 7.53 | 7.78 | 7.28 | 8.15 | 6.90 |
| layer | Doubletex CBS-1 | 0.25 | 0.00 | 0.50 | 0.25 | 0.25 |
| | Tinuvin 400DW | 0.63 | 0.63 | 0.63 | 0.00 | 1.25 |
| | Thickness (mm) | 8.0 | 8.0 | 8.0 | 8.0 | 8.0 |
| Total Thickness of Developer | | 12.0 | 12.0 | 12.0 | 12.0 | 12.0 |
| Layers (mm) | | | | | | |
| Total OB used (g/m2) | | 0.04 | 0.04 | 0.04 | 0.04 | 0.04 |
| OB in Dc (g/m2) | | 0.02 | 0.04 | 0.00 | 0.02 | 0.02 |
| OB in Dp (g/m2) | | 0.02 | 0.00 | 0.04 | 0.02 | 0.02 |
| Total UVA used (g/m2) | | 0.10 | 0.10 | 0.10 | 0.10 | 0.10 |
| UVA in Dc (g/m2) | | 0.05 | 0.05 | 0.05 | 0.10 | 0.00 |
| UVA in Dp (g/m2) | | 0.05 | 0.05 | 0.05 | 0.00 | 0.10 |
| Black | Fresh | 0.51 | 0.52 | 0.53 | 0.50 | 0.52 |
| Density | 3 days | 1.13 | 1.08 | 1.12 | 1.10 | 1.16 |
| (KDmax) | @40° C./85% RH | | | | | |
| | 14 days | 1.17 | 1.13 | 1.18 | 1.19 | 1.22 |
| | @40° C./85% RH | | | | | |
| Yellow | YI, Fresh | 2.4 | 2.6 | 2.3 | 2.3 | 2.4 |
| Index | Δ(YI)_{3 d}, Q-SUN | 20.9 | 19.5 | 19.1 | 20.9 | 18.3 |
| (YI) | Δ(YI)_{3 d} | 0.1 | 0.1 | 0.1 | 0.1 | 0.1 |
| | @40° C./85% RH | | | | | |

It is evident from Table 11 that the addition of optical brighter and UV absorber improved the color stability and reduced the degree of discoloration after aging. With the same total OB coverage of 0.04 g/m² and UVA coverage of 0.10 g/m² (Examples 7-1 to 7-10), all the media showed about the same fresh and 3-day KDmax of 0.50˜0.56 and 1.08˜1.17, respectively. However, the media prepared with the two-layer developer sheets (Examples 7-2 to 7-10) in general showed a significantly less degree of out-door discoloration as indicated by the D (Y.I) 3d after aged in the Q-SUN Chamber for 3 days than the media with only the Dp layer (Example 7-1). It is also evident from Table 11 that the media with two-layer developer sheets showed a higher 14-day KDmax which implied a less degree of fading after aged at 40° C./85% RH for 14 days than that of the media with only the Dp layer.

The two-layer developer structure also provided an additional mechanism to achieve better discoloration resistance by distributing the UVA and OB in the two developer layers. As it can be seen from Examples 7-3 vs. 7-2, 7-5 vs. 7-4, and 7-10 vs. 7-9, the media with all the UVA in the Dp layer showed a better out-door discoloration resistance or a lower D (Y.I) 3d after aged in the Q-SUN chamber than those media with all the UVA in the Dc layer. In contrast, it appears that the media of Examples 7-2 and 7-3 with all the OB in the Dc layer showed a better discoloration resistance than those with all the OB in the Dp layer (Examples 7-2 and 7-3 vs. Examples 7-4 and 7-5, respectively.)

While certain embodiments have been illustrated and described, it should be understood that changes and modifications can be made therein in accordance with ordinary skill in the art without departing from the technology in its broader aspects as defined in the following claims.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, compounds, compositions, or structures, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

1. An imaging system comprising:
a) a microporous developer layer (Dp) comprising one or more dye developers, optionally one or more UV absorbers and optionally one or more optical brighteners; and
b) a low-haze, clear developer layer (Dc) overlying the microporous developer layer and comprising one or more dye developers, optionally one or more optical brighteners and optionally one or more UV absorbers;
wherein the concentration of dye developers in the low-haze, clear developer layer (Dc) is no greater than the concentration of the dye developers in the microporous layer (Dp).

2. The imaging system of claim 1, wherein the one or more dye developer in the microporous layer is the same as the one or more dye developer in the low-haze, clear developer layer.

3. The imaging system of claim 1, wherein the dye developer is amorphous or crystalline.

4. The imaging system of claim 1, wherein the one or more dye developer is a leuco-dye developer.

5. The imaging system of claim 1, wherein the dye developer is selected from the group consisting of Lewis acids, acid clay, phenolic resins, novolac resins, salicylic acid, oxalic acid, phthalic acid, and their derivatives, metal complexes, and copolymers, blends, or composites thereof.

6. The imaging system of claim 1, wherein the dye developer comprises a metal salt of salicylic acid, phenolic resins, novolac resin, and their blends or copolymers.

7. The imaging system of claim 1, wherein the developer is zinc 3, 5-bis(alpha-methylbenzyl) salicylate or zinc 3,5-dialkyl salicylate.

8. The imaging system of claim 1, wherein the low-haze clear developer layer comprises from about 5 wt. % to about 90 wt. %, based on the dry weight of the low-haze clear developer layer, of one or more dye developers.

9. (canceled)

10. The imaging system of claim 1, wherein the microporous developer layer comprises from about 50 wt. % to about 98 wt. %, based on the dry weight of the microporous developer layer, of one or more dye developers.

11. (canceled)

12. The imaging system of claim 1, wherein each of the microporous developer layer and the low-haze clear developer layer further comprises one or more binders.

13. The imaging system of claim 1, wherein the imaging layer has a thickness of from about 6 μm to about 18 μm.

14. The imaging system of claim 1, wherein the microporous developer layer has a thickness of from about 5 μm to about 14 μm.

15. (canceled)

16. The imaging system of claim 1, wherein the low-haze clear developer layer has a thickness of from about 2 μm to about 10 μm.

17. (canceled)

18. The imaging system of claim 1, wherein
(a) the concentration of optical brightener in the low-haze, clear developer layer is no less than the concentration of the optical brightener in the microporous layer, or
(b) wherein the concentration of UV absorber in the low-haze, clear developer layer is no greater than the concentration of the UV absorber in the microporous layer.

19. The imaging system of claim 1, wherein the microporous layer does not include (a) an optical brightener, (b) a UV absorber, or (c) both an optical brighter and a UV absorber.

20.-21. (canceled)

22. The imaging system of claim 1, further comprising an imaging layer in contact with the microporous developer layer and comprising one or more photosensitive microcapsules; said one or more photosensitive microcapsules comprising a leuco-dye and a multifunctional photo-polymerizable or photocrosslinkable monomer or oligomer.

23. The imaging system of claim 22, wherein the one or more photosensitive microcapsules of the imaging layer is photo-hardenable, photo-crosslinkable, or photo-polymerizable.

24. The imaging system of claim 22, wherein the one or more photosensitive microcapsules of the imaging layer comprises a mixture of two or more leuco-dyes, selected from the group consisting of a black leuco-dye, a cyan leuco-dye, a magenta leuco-dye, a yellow leuco-dye, a red leuco-dye, a green leuco-dye, and a blue leuco-dye.

25. The imaging system of claim 1, further comprising an under-layer comprising one or more microcapsules, said one or more microcapsules comprising an internal phase comprising at least one of:
(i) a solvent, plasticizer or a diluent for the leuco-dye in the photosensitive microcapsules of the imaging layer or the leuco-dye developer of the developer layer; or
(ii) a multifunctional photo-polymerizable or cross-linkable monomer or oligomer, and a black leuco-dye or leuco-dye system.

26. The imaging system of claim 25, wherein the under-layer is a primer layer, an adhesive layer, or a tie layer.

27. The imaging system of claim 1, wherein the imaging layer or the under-layer is overlaid on to one surface of a first substrate.

28. The imaging system of claim 1, further comprising a second substrate with the low-haze clear developer layer deposited thereon.

29. An imaging system comprising:
a) a first substrate having two sides;
b) optionally an under-layer overlaying one side of the first substrate, the under-layer comprising one or more microcapsules;
c) an imaging layer overlying the under-layer, the imaging layer comprising one or more photosensitive microcapsules; said photosensitive microcapsules comprising a leuco-dye, a multifunctional photo-polymerizable or photocrosslinkable monomer or oligomer;
d) a microporous developer layer (Dp) comprising one or more leuco-dye developers, one or more UV absorbers and optionally one or more optical brighteners;
e) a low-haze, clear developer layer (Dc) overlying the microporous developer layer and comprising one or more dye developers, one or more optical brighteners and optionally one or more UV absorbers; and optionally
f) a second substrate or a durable layer overlaying the low-haze, clear developer layer.
